(19) United States
(12) Patent Application Publication
(10) Pub. No.: US 2001/0051856 A1
(43) Pub. Date: Dec. 13, 2001

(54) Caching of intra-layer calculations for rapid rigorous coupled-wave analyses

(76) Inventors: Xinhui Niu, San Jose, CA (US); Nickhil Harshavardhan Jakatdar, Fremont, CA (US)

Correspondence Address: Laurence J. Shaw, 3627 Sacramento Street, San Francisco, CA, 94118, US

(21) Appl. No.: 09/764,780

(22) Filed: Jan. 17, 2001

Related U.S. Application Data
(60) Provisional application No. 60/178,910, filed on Jan. 26, 2000.

(51) Int. Cl. G01R 15/00

(52) U.S. Cl. 702/57

(57) ABSTRACT

The diffraction of electromagnetic radiation from periodic grating profiles is determined using rigorous coupled-wave analysis, with intermediate calculations cached to reduce computation time. To implement the calculation, the periodic grating is divided into layers, cross-sections of the ridges of the grating are discretized into rectangular sections, and the permittivity, electric fields and magnetic fields are written as harmonic expansions along the direction of periodicity of the grating. Application of Maxwell's equations to each intermediate layer, i.e., each layer except the atmospheric layer and the substrate layer, provides a matrix wave equation with a wave-vector matrix A coupling the harmonic amplitudes of the electric field to their partial second derivatives in the direction perpendicular to the plane of the grating, where the wave-vector matrix A is a function of intra-layer parameters and incident-radiation parameters. W is the eigenvector matrix obtained from wave-vector matrix A, and Q is a diagonal matrix of square roots of the eigenvalues of the wave-vector matrix A. The requirement of continuity of the fields at boundaries between layers provides a matrix equation in terms of W and Q for each layer boundary, and the solution of the series of matrix equations provides the diffraction reflectivity. Look-up of W and Q, which are precalculated and cached for a useful range of intra-layer parameters (i. e., permittivity harmonics, periodicity lengths, ridge widths, ridge offsets) and incident-radiation parameters (i.e., wavelengths and angles of incidence), provides a substantial reduction in computation time for calculating the diffraction reflectivity.

### RELATED DOCUMENTS

The present patent application is based on provisional patent application serial No. 60/178,910, filed Jan. 26, 2000, by Xinhui Niu and Nickhil Harshavardhan Jakatdar, entitled Cached Coupled Wave Method for Diffraction Grating Profile Analysis.

### BACKGROUND OF THE INVENTION

The present invention relates generally to the caching of intermediate results, and the use of cached intermediate results to increase the efficiency of calculations. The present invention also relates to the coupled wave analyses of diffraction from periodic gratings. More particularly the present invention relates to apparatus and methods for reducing the computation time of coupled wave analyses of diffraction from periodic gratings, and still more particularly the present invention relates to apparatus and methods for caching and retrieval of intermediate computations to reduce the computation time of coupled wave analyses of diffraction from periodic gratings.

Diffraction gratings have been used in spectroscopic applications, i.e., diffraction applications utilizing multiple wavelengths, such as optical instruments, space optics, synchrotron radiation, in the wavelength range from visible to x-rays. Furthermore, the past decades have seen the use of diffraction gratings in a wide variety of nonspectroscopic applications, such as wavelength selectors for tunable lasers, beam-sampling elements, and dispersive instruments for multiplexers.

The ability to determine the diffraction characteristics of periodic gratings with high precision is useful for the refinement of existing applications. Furthermore, the accurate determination of the diffraction characteristics of periodic gratings is useful in extending the applications to which diffraction gratings may be applied. However, it is well known that modeling of the diffraction of electromagnetic radiation from periodic structures is a complex problem that requires sophisticated techniques. Closed analytic solutions are restricted to geometries which are so simple that they are of little interest, and current numerical techniques generally require a prohibitive amount of computation time.

The general problem of the mathematical analysis of electromagnetic diffraction from periodic gratings has been addressed using a variety of different types of analysis, and several rigorous theories have been developed in the past decades. Methods using integral formulations of Maxwell's equations were used to obtain numerical results by A. R. Neureuther and K. Zaki (“Numerical methods for the analysis of scattering from nonplanar periodic structures,” Intn'l URSI Symposium on Electromagnetic Waves, Stresa, Italy, 282-285, 1969) and D. Maystre (“A new general integral theory for dielectric coated gratings,” .J Opt. Soc. Am., vol. 68, no. 4, 490-495, April 1978). Methods using differential formulations of Maxwell's equations have also been developed by a number of different groups. For instance, an iterative differential formulation has been developed by M. Neviere, P. Vincent, R. Petit and M. Cadilhac (“Systematic study of resonances of holographic thin film couplers,” Optics Communications, vol. 9, no. 1, 48-53, Sept. 1973), and the rigorous coupled-wave analysis method has been developed by M. G. Moharam and T. K. Gaylord (“Rigorous Coupled-Wave Analysis of Planar-Grating Diffraction,” J. Opt. Soc. Am., vol. 71, 811-818, July 1981). Further work in differential formulations has been done by E. B. Grann and D. A. Pommet (“Formulation for Stable and Efficient Implementation of the Rigorous Coupled-Wave Analysis of Binary Gratings,” J. Opt. Soc. Am. A, vol. 12, 1068-1076, May 1995), and E. B. Grann and D. A. Pommet (“Stable Implementation of the Rigorous Coupled-Wave Analysis for Surface-Relief Dielectric Gratings: Enhanced Transmittance Matrix Approach”, J. Opt. Soc. Am. A, vol. 12, 1077-1086, May 1995).

Conceptually, an RCWA computation consists of four steps:

The grating is divided into a number of thin, planar layers, and the section of the ridge within each layer is approximated by a rectangular slab.

Within the grating, Fourier expansions of the electric field, magnetic field, and permittivity leads to a system of differential equations for each layer and each harmonic order.

Boundary conditions are applied for the electric and magnetic fields at the layer boundaries to provide a system of equations.

Solution of the system of equations provides the diffracted reflectivity from the grating for each harmonic order.

The accuracy of the computation and the time required for the computation depend on the number of layers into which the grating is divided and the number of orders used in the Fourier expansion.

A number of variations of the mathematical formulation of RCWA have been proposed. For instance, variations of RCWA proposed by P. Lalanne and G. M. Morris (“Highly Improved Convergence of the Coupled-Wave Method for TM Polarization,” J. Opt. Soc. Am. A, 779-784, 1996), L. Li and C. Haggans (“Convergence of the coupled-wave method for metallic lamellar diffraction gratings”, J. Opt. Soc. Am. A, 1184-1189, June, 1993), and G. Granet and B. Guizal (“Efficient Implementation of the Coupled-Wave Method for Metallic Lamellar Gratings in TM Polarization”, J. Opt. Soc. Am. A, 1019-1023, May, 1996) differ as whether the Fourier expansions are taken of the permittivity or the reciprocal of the permittivity. (According to the lexography of the present specification, all of these variations are considered to be “RCWA.”) For a specific grating structure, there can be substantial differences in the numerical convergence of the different formulations due to differences in the singularity of the matrices involved in the calculations, particularly for TM-polarized and conically-polarized incident radiation. Therefore, for computational efficiency it is best to select amongst the different formulations.

Frequently, the profiles of a large number of periodic gratings must be determined. For instance, in determining the ridge profile which produced a measured diffraction spectrum in a scatterometry application, thousands or even millions of profiles must be generated, the diffraction spectra of the profiles are calculated, and the calculated diffraction spectra are compared with the measured diffraction spectrum to find the calculated diffraction spectrum which most closely matches the measured diffraction spectrum. Further examples of scatterometry applications which require the analysis of large numbers of periodic gratings include U.S. Pat. Nos. 5,164,790, 5,867,276 and 5,963,329, and “Specular Spectroscopic Scatterometry in DUV lithography,” X. Niu, N. Jakatdar, J. Bao and C.J. Spanos, SPIE, vol. 3677, pp. 159-168, from thousands to millions of diffraction profiles must be analyzed. However, using an accurate method such as RCWA, the computation time can be prohibitively long. Thus, there is a need for methods and apparatus for rapid and accurate analysis of diffraction data to determine the profiles of periodic gratings.

It is therefore object of the present invention to provide methods and apparatus for determination of a cross-sectional profile of a periodic grating via analysis of diffraction data, and more particularly via analysis of broadband electromagnetic radiation diffracted from the periodic grating.

Furthermore, it is an object of the present invention to provide methods and apparatus for rapid RCWA calculations.

More particularly, it is object of the present invention to provide methods and apparatus for caching of intermediate calculations to reduce the calculation time of RCWA.

Still more particularly, it is object of the present invention to provide methods and apparatus for caching of computationally-expensive RCWA calculation results which are dependent on intra-layer parameters, or intra-layer and incident-radiation parameters.

It is another object of the present invention to provide methods and apparatus for the use of cached, computationally-expensive calculation results in RCWA calculations.

Additional objects and advantages of the present application will become apparent upon review of the Figures, Detailed Description of the Present Invention, and appended Claims.

### SUMMARY OF THE INVENTION

The present invention is directed to a method for reducing the computation time of rigorous coupled-wave analyses (RCWA) of the diffraction of electromagnetic radiation from a periodic grating. RCWA calculations involve the division of the periodic grating into layers, with the initial layer being the atmospheric space above the grating, the last layer being the substrate below the grating, and the periodic features of the grating lying in intermediate layers between the atmospheric space and the substrate. A cross-section of the periodic features is discretized into a plurality of stacked rectangular sections, and within each layer the permittivity, and the electric and magnetic fields of the radiation are formulated as a sum of harmonic components along the direction of periodicity of the grating.

Application of Maxwell's equations provides an intra-layer matrix equation in each of the intermediate layers I of the form

$$[ \frac{{\partial }^{2} {S}_{l , y}}{\partial {z}^{′2}} ] = [ {A}_{l} ] [ {S}_{l , y} ]$$

where S_{l,y} are harmonic amplitudes of an electromagnetic field, z is the perpendicular to the periodic grating, and the wave-vector matrix A₁ is only dependent on intra-layer parameters and incident-radiation parameters. A homogeneous solution of the intra-layer matrix equation involves an expansion of the harmonic amplitudes S_{l,y} into exponential functions dependent on eigenvectors and eigenvalues of said wave-vector matrix Aₗ.

According to the present invention, a layer-property parameter region, an incident-radiation parameter region, a layer-property parameter-region sampling, and an incident-radiation parameter-region sampling are determined. Also, a maximum harmonic order to which the electromagnetic fields are to be computed is determined. The required permittivity harmonics are calculated for each layer-property value, as determined by the layer-property parameter-region sampling of the layer-property parameter region. The wave-vector matrix A and its eigenvectors and eigenvalues are calculated for each layer-property value and each incident-radiation value, as determined by the incident-radiation parameter-region sampling of the incident-radiation parameter region. The calculated eigenvectors and eigenvalues are stored in a memory for use in analysis of the diffraction of incident electromagnetic radiation from the periodic grating.

### BRIEF DESCRIPTION OF THE FIGURES

FIG. 1 shows a section of a diffraction grating labeled with variables used in the mathematical analysis of the present invention.

FIG. 2 shows a cross-sectional view of a pair of ridges labeled with dimensional variables used in the mathematical analysis of the present invention.

FIG. 3 shows a process flow of a TE-polarization rigorous coupled-wave analysis.

FIG. 4 shows a process flow for a TM-polarization rigorous coupled-wave analysis.

FIG. 5 shows a process flow for the pre-computation and caching of calculation results dependent on intra-layer and incident-radiation parameters according to the method of the present invention.

FIG. 6 shows a process flow for the use of cached calculation results dependent on intra-layer and incident-radiation parameters according to the method of the present invention.

FIG. 7A shows an exemplary ridge profile which is discretized into four stacked rectangular sections.

FIG. 7B shows an exemplary ridge profile which is discretized into three stacked rectangular sections, where the rectangular sections have the same dimensions and x-offsets as three of the rectangular section found in the ridge discretization of FIG. 7A.

FIG. 8 shows the apparatus for implementation of the present invention.

### DETAILED DESCRIPTION OF THE PREFERRED EMBODIMENT

The method and apparatus of the present invention dramatically reduces the computation time required for RCWA computations by pre-processing and caching intra-layer information and incident-radiation information, and using the cached intra-layer and incident-radiation information for RCWA calculations.

Section 1 of the present Detailed Description describes the mathematical formalism for RCWA calculations for the diffraction of TE-polarized incident radiation from a periodic grating. Definitions of the variables used in the present specification are provided, and intra-layer Fourier-space versions of Maxwell's equations are presented and solved, producing z-dependent electromagnetic-field harmonic amplitudes, where z is the direction normal to the grating. Formulating the electromagnetic-field harmonic amplitudes in each layer as exponential expansions produces an eigenequation for a wave-vector matrix dependent only on intra-layer parameters and incident-radiation parameters. Coefficients and exponents of the exponential harmonic amplitude expansions are functions of the eigenvalues and eigenvectors of the wave-vector matrices. Application of inter-layer boundary conditions produces a boundary-matched system matrix equation, and the solution of the boundary-matched system matrix equation provides the remaining coefficients of the harmonic amplitude expansions.

Section 2 of the present Detailed Description describes mathematical formalisms for RCWA calculations of the diffracted reflectivity of TM-polarized incident radiation which parallels the exposition of Section 1.

Section 3 of the present Detailed Description presents a preferred method for the solution of the boundary-matched system matrix equation.

Section 4 of the present Detailed Description describes the method and apparatus of the present invention. Briefly, the pre-calculation/caching portion of the method of the present invention involves:

selection of an intra-layer parameter region, an intra-layer parameter sampling, an incident-radiation parameter region, and an incident-radiation parameter sampling;

generation of wave-vector matrices for intra-layer parameters spanning the intra-layer parameter region, as determined by the intra-layer parameter sampling, and incident-radiation parameters spanning the incident-radiation parameter region, as determined by the incident-radiation parameter sampling;

solution for the eigenvectors and eigenvalues of the wave-vector matrices in the investigative region; and

caching of the eigenvectors and eigenvalues of the wave-vector matrices.

Briefly, the portion of the method of the present invention for the use of the cached computations to calculate the diffracted reflectivity produced by a periodic grating includes the steps of:

discretization of the profile of a ridge of the periodic grating into layers of rectangular slabs;

retrieval from cache of the eigenvectors and eigenvalues for the wave-vector matrix corresponding to each layer of the profile;

compilation of the retrieved eigenvectors and eigenvalues for each layer to produce a boundary-matched system matrix equation; and

solution of the boundary-matched system matrix equation to provide the diffracted reflectivity.

1. Rigorous Coupled-Wave Analysis for TE-Polarized Incident Radiation

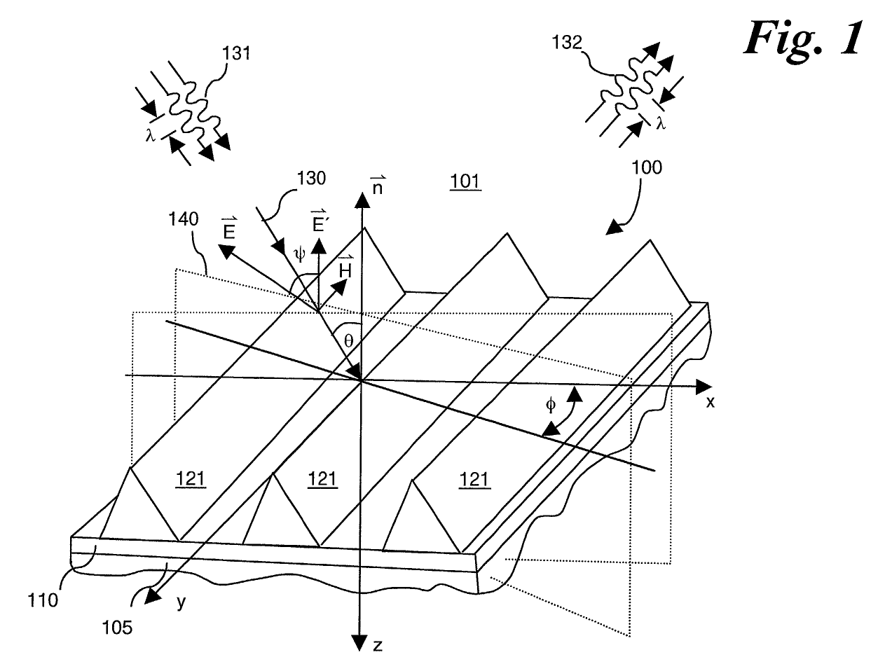

A section of a periodic grating 100 is shown in FIG. 1. The section of the grating 100 which is depicted includes three ridges 121 which are shown as having a triangular cross-section. It should be noted that the method of the present invention is applicable to cases where the ridges have shapes which are considerably more complex, and even to cases where the categories of “ridges” and “troughs” may be ill-defined. According to the lexography of the present specification, the term “ridge” will be used for one period of a periodic structure on a substrate. Each ridge 121 of FIG. 1 is considered to extend infinitely in the +y and −y directions, and an infinite, regularly-spaced series of such ridges 121 are considered to extend in the +x and −x directions. The ridges 121 are atop a deposited film 110, and the film 110 is atop a substrate 105 which is considered to extend semi-infinitely in the +z direction. The normal vector n to the grating is in the −z direction.

FIG. 1 illustrates the variables associated with a mathematical analysis of a diffraction grating according to the present invention. In particular:

θ is the angle between the Poynting vector 130 of the incident electromagnetic radiation 131 and the normal vector \vec{n} of the grating 100. The Poynting vector 130 and the normal vector \vec{n} define the plane of incidence 140.

φ is the azimuthal angle of the incident electromagnetic radiation 131, i.e., the angle between the direction of periodicity of the grating, which in FIG. 1 is along the x axis, and the plane of incidence 140. (For ease of presentation, in the mathematical analysis of the present specification the azimuthal angle φ is set to zero.)

ψ is the angle between the electric-field vector \vec{E} of the incident electromagnetic radiation 131 and the plane of incidence 140, i.e., between the electric field vector \vec{E} and its projection \vec{E}′ on the plane of incidence 140. When φ=0 and the incident electromagnetic radiation 131 is polarized so that ψ=π/2, the electric-field vector \vec{E} is perpendicular to the plane of incidence 140 and the magnetic-field vector \vec{H} lies in the plane of incidence 140, and this is referred to as the TE polarization. When φ=0 and the incident electromagnetic radiation 131 is polarized so that ψ=0, the magnetic-field vector \vec{H} is perpendicular to the plane of incidence 140 and the electric-field vector \vec{E} lies in the plane of incidence 140, and this is referred to as the TM polarization. Any planar polarization is a combination of in-phase TE and TM polarizations. The method of the present invention described below can be applied to any polarization which is a superposition of TE and TM polarizations by computing the diffraction of the TE and TM components separately and summing them. Furthermore, although the ‘off-axis’ φ≢0 case is more complex because it cannot be separated into TE and TM components, the present invention is applicable to off-axis incidence radiation as well.

λ is the wavelength of the incident electromagnetic radiation 131.

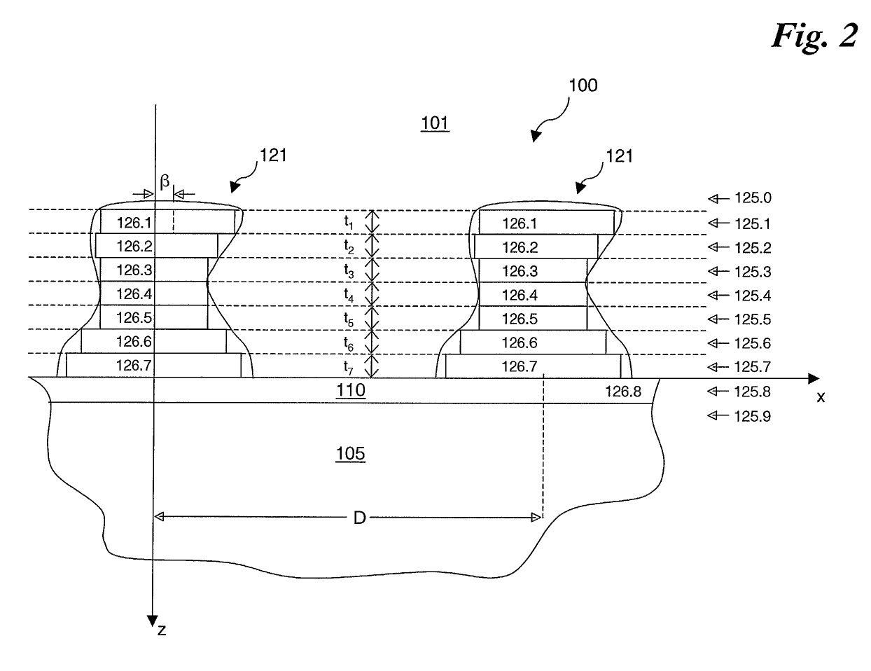

FIG. 2 shows a cross-sectional view of two ridges 121 of an exemplary periodic grating 100 (which will be labeled using the same reference numerals as the grating of FIG. 1.), illustrating the variables associated with a mathematical description of the dimensions of the diffraction grating 100 according to the present invention. In particular:

L is the number of the layers into which the system is divided. Layers O and L are considered to be semi-infinite layers. Layer O is an “atmospheric” layer 101, such as vacuum or air, which typically has a refractive index n_{O} of unity. Layer L is a “substrate” layer 105, which is typically silicon or germanium in semiconductor applications. In the case of the exemplary grating 100 of FIG. 2, the grating 100 has ten layers with the atmospheric layer 101 being the zeroeth layer 125.0, the ridges 121 being in the first through seventh layers 125.1 through 125.7, the thin film 110 being the eighth layer 125.8, and the substrate 105 being the ninth layer 125.9. (For the mathematical analysis described below, the thin-film 110 is considered as a periodic portion of the ridge 121 with a width d equal to the pitch D.) The portion of ridge 121 within each intermediate layer 125.1 through 125.(L-1) is approximated by a thin planar slab 126 having a rectangular cross-section. (Generically or collectively, the layers are assigned reference numeral 125, and, depending on context, “layers 125” may be considered to include the atmospheric layer 101 and/or the substrate 105.) Clearly, any geometry of ridges 121 with a cross-section which does not consist solely of vertical and horizontal sections is best approximated using a large number of layers 125.

D is the periodicity length or pitch, i.e., the length between equivalent points on pairs of adjacent ridges 121 .

dₗ is the width of the rectangular ridge slab 126.l in the lth layer 125.l.

tₗ is the thickness of the rectangular ridge slab 126.l in the lth layer 125.1 for 1<l <(L-1). The thicknesses tₗ of the layers 125 are chosen such that every vertical line segment within a layer 125 passes through only a single material. For instance, if in FIG. 2 the materials in layers 125.4, 125.5, and 125.6 are the same, but different than the materials in layers 125.3 and 125.7, than it would be acceptable to combine layers 125.4 and 125.5, or layers 125.5 and 125.6, or layers 125.4, 125.5 and 125.6 into a single layer. However, it would not be acceptable to combine layers 125.3 and 125.4, or layers 125.6 and 125.7 into a single layer.

nₗ is the index of refraction of the material in the rectangular ridge slab 126 of the lth layer 125.l.

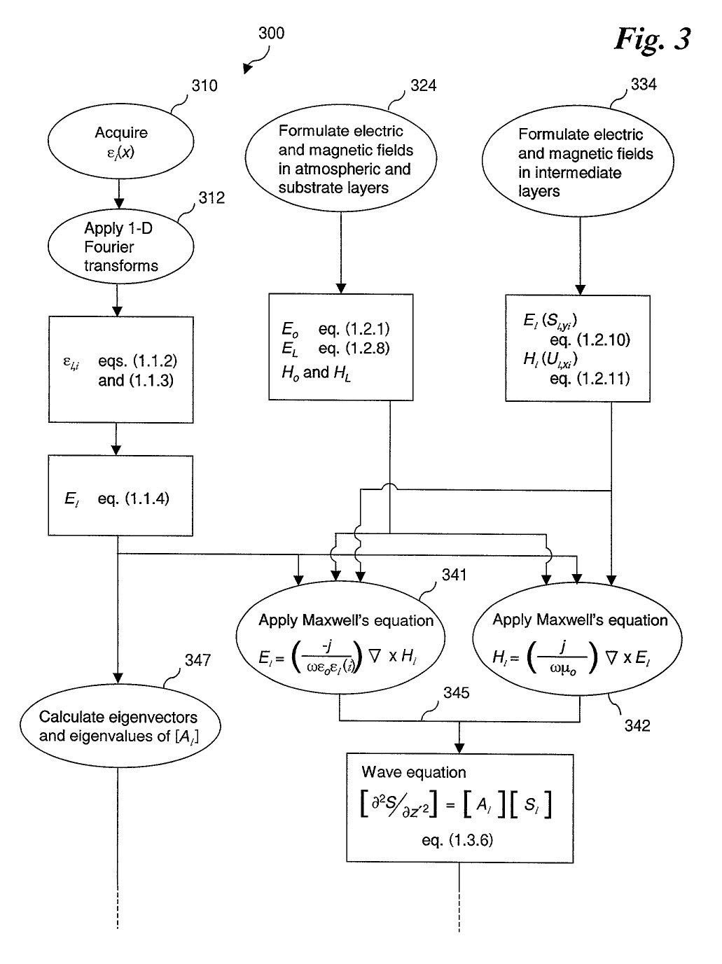

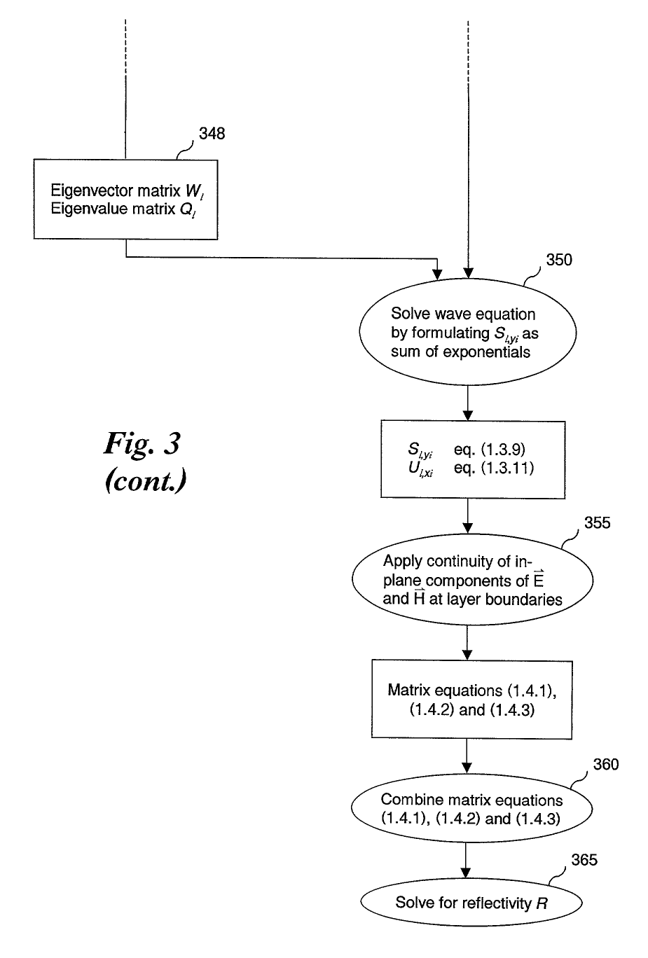

In determining the diffraction generated by grating 100, a Fourier space version of Maxwell's equations is used. As shown in the calculation process flow diagram of FIG. 3, the permittivities ε(x) for each layer l are determined or acquired 310 (for instance, according to the method described in provisional patent application serial No. 60/178,540, filed Jan. 26, 2000, entitled Profiler Business Model, by the present inventors, and provisional patent application serial No. 60/209,424, filed Jun. 2, 2000, entitled Profiler Business Model, by the present inventors, both of which are incorporated herein by reference), and a one-dimensional Fourier transformation of the permittivity εₗ(x) of each layer l is performed 312 along the direction of periodicity, \hat{x}, of the periodic grating 100 to provide the harmonic components of the permittivity ε_{l,i}, where i is the order of the harmonic component. (In FIGS. 3, 4, 5 and 6, process steps are shown enclosed within ovals or rectangles with rounded corners, and the results of calculations are shown enclosed within rectangles with sharp comers. When appropriate in FIG. 3, equation numbers are used in lieu of, or in addition to, reference numerals.) In particular, the real-space permittivity ε(x) of the lth layer is related to the permittivity harmonics ε_{l,i} of the lth layer by

$${ϵ}_{l} ( x ) = {\sum }_{l = - ∞}^{∞} {ϵ}_{l , i} exp ( j \frac{2 π i}{D} x ) . \qquad \text{(1.1.1)}$$

Therefore, via the inverse transform,

$${ϵ}_{l , 0} = {n}_{r}^{2} \frac{{d}_{l}}{D} + {n}_{0}^{2} ( 1 - \frac{{d}_{l}}{D} ) , \qquad \text{(1.1.2)}$$

and for i not equal to zero,

$${ϵ}_{l , i} = ( {n}_{r}^{2} - {n}_{0}^{2} ) \frac{sin ( π i \frac{{d}_{l}}{D} )}{π i} {ⅇ}^{- j π i β / D} , \qquad \text{(1.1.3)}$$

where nᵣ is the index of refraction of the material in the ridges 121 in layer l, the index of refraction n_{O} of the atmospheric layer l01 is typically near unity, and β is the x-offset of the center of the central rectangular ridge slab 126.l (i.e., the ridge 121 nearest x=0, where generally it is attempted to position the x=0 point at the center of a ridge 121 ) from the origin. The present specification explicitly addresses periodic gratings where a single ridge material and a single atmospheric material are found along any line in the x-direction. However, as per disclosure document serial number 474051, filed May 15, 2000, entitled Optical Profilometry for Sub-Micron Periodic Features with Three or More Materials in a Layer, by the same inventors, the present invention may be applied to gratings having more than one ridge material along a line in the x-direction.

According to the mathematical formulation of the present invention, it is convenient to define the (2o+1)×(2o+1) Toeplitz-form, permittivity harmonics matrix Eₗ

$${E}_{l} = [ \begin{matrix}{ϵ}_{l , 0} & {ϵ}_{l , - 1} & {ϵ}_{l , - 2} & ⋯ & {ϵ}_{l , - 2 o} \\ {ϵ}_{l , 1} & {ϵ}_{l , 0} & {ϵ}_{l , - 1} & ⋯ & {ϵ}_{l , - ( 2 o - 1 )} \\ {ϵ}_{l , 2} & {ϵ}_{l , 1} & {ϵ}_{l , 0} & ⋯ & {ϵ}_{l , - ( 2 o - 2 )} \\ ⋯ & ⋯ & ⋯ & ⋯ & ⋯ \\ {ϵ}_{l , 2 o} & {ϵ}_{l , ( 2 o - 1 )} & {ϵ}_{l , ( 2 o - 2 )} & ⋯ & {ϵ}_{l ,}\end{matrix} ] . \qquad \text{(1.1.4)}$$

As will be seen below, to perform a TE-polarization calculation where oth-order harmonic components of the electric field \vec{E} and magnetic field \vec{H} are used, it is necessary to use harmonics of the permittivity ε_{l,i} up to order 2o.

For the TE polarization, in the atmospheric layer the electric field \vec{E} is formulated 324 as

$${\vec{E}}_{0 , y} = exp ( - {jk}_{0} {n}_{0} ( sin θ x + cos θ z ) + {\sum }_{i} {R}_{i} exp ( - j ( {k}_{xi} x - {k}_{0 , zi} z ) ) , \qquad ( 1.2 .1 )$$

where the term on the left of the right-hand side of equation (1.2.1) is an incoming plane wave at an angle of incidence θ, the term on the right of the right-hand side of equation (1.2.1) is a sum of reflected plane waves and Rₗ is the magnitude of the ith component of the reflected wave, and the wave vectors k_{O} and (kₓₗ, k_{O,zl}) are given by

$$\begin{matrix}{k}_{0} = \frac{2 π}{λ} = {ω ( {μ}_{0} {ϵ}_{0} )}^{1 / 2} , & ( 1.2 .2 ) \\ {k}_{xi} = {k}_{0} ( {n}_{0} sin ( θ ) - i ( \frac{λ}{D} ) ) , \\ and & \text{(1.2.3)} \\ {k}_{0 , zi} = \{ \begin{matrix}{{k}_{0} ( {n}_{l}^{2} - {( {k}_{xi} / {k}_{0} )}^{2} )}^{1 / 2} \\ - {{jk}_{0} ( {n}_{l}^{2} - {( {k}_{xi} / {k}_{0} )}^{2} )}^{1 / 2}\end{matrix} . & \text{(1.2.4)}\end{matrix}$$

where the value of k_{O,zl} is chosen from equation (1.2.4), i.e., from the top or the bottom of the expression, to provide Re(k_{O,zi})−Im(k_{O,zl})>0. This insures that k_{O,zl}², has a positive real part, so that energy is conserved. It is easily confirmed that in the atmospheric layer 101, the reflected wave vector (kₓᵢ, k_{O,zl}) has a magnitude equal to that of the incoming wave vector k_{O}n_{O}. The magnetic field \vec{H} in the atmospheric layer l01 is generated from the electric field \vec{E} by Maxwell's equation (1.3.1) provided below.

The x-components kₓₗ of the outgoing wave vectors satisfy the Floquet condition (which is also called Bloch's Theorem, see Solid State Physics, N. W. Ashcroft and N. D. Mermin, Saunders College, Philadelphia, 1976, pages 133-134) in each of the layers 125 containing the periodic ridges 121 , and therefore, due to the boundary conditions, in the atmospheric layer l01 and the substrate layer l05 as well. That is, for a system having an n-dimensional periodicity given by

$$f ( \vec{r} ) = f ( \vec{r} + {\sum }_{i = 1}^{n} {m}_{i} {\vec{d}}_{i} ) , \qquad \text{(1.2.5)}$$

where \vec{d}ₗ are the basis vectors of the periodic system, and mₗ takes on positive and negative integer values, the Floquet condition requires that the wave vectors \vec{k} satisfy

$$\vec{k} = {\vec{k}}_{0} + 2 π {\sum }_{i = 1}^{n} {m}_{i} {\vec{b}}_{i} , \qquad \text{(1.2.6)}$$

where \vec{b}ₗ are the reciprocal lattice vectors given by

(\vec{b}ₗ·\vec{d}ⱼ)=δ_{y}, (1.2.7)

\vec{k}_{O} is the wave vector of a free-space solution, and δ_{y} is the Kronecker delta finction. In the case of the layers 125 of the periodic grating 100 of FIGS. 1 and 2 which have the single reciprocal lattice vector \vec{b} is \hat{x}/D, thereby providing the relationship of equation (1.2.3).

It may be noted that the formulation given above for the electric field in the atmospheric layer l01, although it is an expansion in terms of plane waves, is not determined via a Fourier transform of a real-space formulation. Rather, the formulation is produced 324 a priori based on the Floquet condition and the requirements that both the incoming and outgoing radiation have wave vectors of magnitude n_{O}k_{O}. Similarly, the plane wave expansion for the electric field in the substrate layer l05 is produced 324 a priori. In the substrate layer l05, the electric field \vec{E} is formulated 324 as a transmitted wave which is a sum of plane waves where the x-components kₓₗ of the wave vectors (kₓᵢ, k_{O,zi}) satisfy the Floquet condition, i.e.,

$$\begin{matrix}{\vec{E}}_{L , y} = {\sum }_{i} {T}_{i} exp ( - j ( {k}_{xi} x + {k}_{L , zi} ( z - {\sum }_{l = 1}^{L - 1} {t}_{l} ) ) ) , \\ where & \text{(1.2.8)} \\ {k}_{L , zi} = \{ \begin{matrix}{{k}_{0} ( {n}_{L}^{2} - {( {k}_{xi} / {k}_{0} )}^{2} )}^{1 / 2} \\ - {{jk}_{0} ( {n}_{L}^{2} - {( {k}_{xi} / {k}_{0} )}^{2} )}^{1 / 2}\end{matrix} . & \text{(1.2.9)}\end{matrix}$$

where the value of k_{L,zl} is chosen from equation (1.2.9), i.e., from the top or the bottom of the expression, to provide Re(k_{L,zi})−Im(k_{L,zl})>0, insuring that energy is conserved.

The plane wave expansions for the electric and magnetic fields in the intermediate layers 125.1 through 125.(L-1) are also produced 334 apriori based on the Floquet condition. The electric field \vec{E}_{l,y} in the lth layer is formulated 334 as a plane wave expansion along the direction of periodicity, \hat{x}, i.e.,

$${\vec{E}}_{l , y} = {\sum }_{i} {S}_{l , yi} s ( z ) exp ( - {jk}_{xi} x ) , \qquad ( 1.2 .10 )$$

\vec{E}_{l,y}=ΣS_{l,yl}(z) exp(−jkₓₗx), (1.2.10)

where S_{l,yl} (z) is the z-dependent electric field harmonic amplitude for the lth layer and the ith harmonic. Similarly, the magnetic field \vec{H}_{l,y} in the lth layer is formulated 334 as a plane wave expansion along the direction of periodicity, \hat{x}, i.e.,

$${\vec{H}}_{l , x} = - {j ( \frac{{ϵ}_{0}}{{μ}_{0}} )}^{1 / 2} {\sum }_{i} {U}_{l , xi} ( z ) exp ( - {jk}_{xi} x ) , \qquad \text{(1.2.11)}$$

where U_{l,xl} (z) is the z-dependent magnetic field harmonic amplitude for the lth layer and the ith harmonic.

According to Maxwell's equations, the electric and magnetic fields within a layer are related by

$${\vec{H}}_{l} = ( \frac{j}{ω {μ}_{0}} ) ∇ \times {\vec{E}}_{l} , \qquad \text{(1.3.1)}$$

and

$${\vec{E}}_{l} = ( \frac{- j}{{ωϵ}_{0} {ϵ}_{l} ( x )} ) ∇ \times {\vec{H}}_{l} . \qquad \text{(1.3.2)}$$

Applying 342 the first Maxwell's equation (1.3.1) to equations (1.2.10) and (1.2.11) provides a first relationship between the electric and magnetic field harmonic amplitudes Sₗ and Uₗ of the lth layer:

$$\frac{\partial {S}_{l , yi} ( z )}{\partial z} = {k}_{0} {U}_{l , xi} . \qquad \text{(1.3.3)}$$

Similarly, applying 341 the second Maxwell's equation (1.3.2) to equations (1.2.10) and (1.2.11), and taking advantage of the relationship

$${k}_{xi} + \frac{2 π h}{D} = {k}_{x ( i - h )} \qquad \text{(1.3.4)}$$

which follows from equation (1.2.3), provides a second relationship between the electric and magnetic field harmonic amplitudes Sₗ and Uₗ for the lth layer:

$$\frac{\partial {U}_{l , xi}}{\partial z} = ( \frac{{k}_{xi}^{2}}{{k}_{0}} ) {S}_{l , yi} - {k}_{0} {\sum }_{p} {ϵ}_{( i - p )} {S}_{l , yp} . \qquad \text{(1.3.5)}$$

While equation (1.3.3) only couples harmonic amplitudes of the same order i, equation (1.3.5) couples harmonic amplitudes Sₗ and Uₗ between harmonic orders. In equation (1.3.5), permittivity harmonics εᵢ from order −2o to +2o are required to couple harmonic amplitudes Sₗ and Uₗ of orders between −o and +o.

Combining equations (1.3.3) and (1.3.5) and truncating the calculation to order o in the harmonic amplitude S provides 345 a second-order differential matrix equation having the form of a wave equation, i. e.,

$$[ \frac{{\partial }^{2} {S}_{l , y}}{\partial {z}^{′2}} ] = [ {A}_{l} ] [ {S}_{l , y} ] , \qquad \text{(1.3.6)}$$

z′=k_{O} z, the wave-vector matrix [Aₗ] is defined as

[Aₗ]=[Kₓ]²−[Eₗ], (1.3.7)

where [Kₓ] is a diagonal matrix with the (i,i) element being equal to (kₓₗ/k_{O}), the permittivity harmonics matrix [Eₗ] is defined above in equation (1.1.4), and [S_{l,y}] and [∂²S_{l,y}/∂z′²] are column vectors with indices i running from −o to +o, i.e.,

$$[ {S}_{l , y} ] = [ \begin{matrix}{S}_{l , y , ( - o )} \\ ⋮ \\ {S}_{l , y , 0} \\ ⋮ \\ {S}_{l , y , o}\end{matrix} ] , \qquad \text{(1.3.8)}$$

By writing 350 the homogeneous solution of equation (1.3.6) as an expansion in pairs of exponentials, i.e.,

$${S}_{l , yi} ( z ) = {\sum }_{m = 1}^{2 o + 1} {w}_{l , i , m} [ {c1}_{l , m} exp ( - {k}_{0} {q}_{l , m} z ) + {c2}_{l , m} exp ( {k}_{0} {q}_{l , m} ( z - {t}_{l} ) ) ] , \qquad \text{(1.3.9)}$$

its functional form is maintained upon second-order differentiation by z′, thereby taking the form of an eigenequation. Solution 347 of the eigenequation

[Aₗ][Wₗ]=[Wₗ][τₗ], (1.3.10)

provides 348 a diagonal eigenvalue matrix [τₗ] formed from the eigenvalues τ_{l,m} of the wave-vector matrix [Aₗ], and an eigenvector matrix [Wₗ] of entries W_{l,i,m}, where W_{l,i,m} is the ith entry of the mth eigenvector of [Aₗ]. A diagonal root-eigenvalue matrix [Qₗ] is defined to be diagonal entries q_{l,i} which are the positive real portion of the square roots of the eigenvalues τ_{l,i}. The constants c1 and c2 are, as yet, undetermined.

By applying equation (1.3.3) to equation (1.3.9) it is found that

$${U}_{l , xi} ( z ) = {\sum }_{m = 1}^{2 o + 1} {v}_{l , i , m} [ - {c1}_{l , m} exp ( - {k}_{0} {q}_{l , m} z ) + {c2}_{l , m} exp ( {k}_{0} {q}_{l , m} ( z - {t}_{l} ) ) ] \qquad \text{(1.3.11)}$$

where v_{l,i,m}=q_{l,m}w_{l,i,m}. The matrix [Vₗ], to be used below, is composed of entries v_{l,i,m}.

The constants c1 and c2 in the homogeneous solutions of equations (1.3.9) and (1.3.11) are determined by applying 355 the requirement that the tangential electric and magnetic fields be continuous at the boundary between each pair of adjacent layers 125.l/125.(l+1). At the boundary between the atmospheric layer l01 and the first layer 125.1, continuity of the electric field E_{y} and the magnetic field Hₓ requires

$$[ \begin{matrix}{δ}_{i0} \\ {jn}_{0} cos ( θ ) {δ}_{i0}\end{matrix} ] + [ \begin{matrix}I \\ - {jY}_{0}\end{matrix} ] R = [ \begin{matrix}{W}_{1} & {W}_{1} {X}_{1} \\ {V}_{1} & - {V}_{1} {X}_{1}\end{matrix} ] [ \begin{matrix}{c1}_{1} \\ {c2}_{1}\end{matrix} ] \qquad \text{(1.4.1)}$$

where Y_{O} is a diagonal matrix with entries (k_{O,zi}/k_{O}), Xₗ is a diagonal layer-translation matrix with elements exp(−k_{O} q_{l,m} tₗ), R is a vector consisting of entries from R₋ₒ to R₊₀ and C1ₗ and c2ₗ are vectors consisting of entries from c1_{l,O} and C1_{l,2o+1}, and c2_{l,O} and c2_{l,2o+1}, respectively. The top half of matrix equation (1.4.1) provides matching of the electric field E_{y} across the boundary of the atmospheric layer l25.0 and the first layer 125. 1, the bottom half of matrix equation (1.4.1.) provides matching of the magnetic field Hₓ across the layer boundary 125.0/125.1, the vector on the far left is the contribution from the incoming radiation 131 in the atmospheric layer l01, the second vector on the left is the contribution from the reflected radiation 132 in the atmospheric layer l01, and the portion on the right represents the fields E_{y} and Hₓ in the first layer l25.1.

At the boundary between adjacent intermediate layers 125.l and 125.(l+1), continuity of the electric field E_{y} and the magnetic field Hₓ requires

$$[ \begin{matrix}{W}_{l - 1} {X}_{l - 1} & {W}_{l - 1} \\ {W}_{l - 1} {X}_{l - 1} & - {V}_{l - 1}\end{matrix} ] [ \begin{matrix}{c1}_{l - 1} \\ {c2}_{l - 1}\end{matrix} ] = [ \begin{matrix}{W}_{l} & {W}_{l} {X}_{l} \\ {V}_{l} & - {V}_{l} {X}_{l}\end{matrix} ] [ \begin{matrix}{c1}_{l} \\ {c2}_{l}\end{matrix} ] , \qquad \text{(1.4.2)}$$

where the top and bottom halves of the vector equation provide matching of the electric field E_{y} and the magnetic field Hₓ, respectively, across the l-1/l layer boundary.

At the boundary between the (L-1)th layer l25.(L-1) and the substrate layer 105, continuity of the electric field E_{y} and the magnetic field Hₓ requires

$$[ \begin{matrix}{W}_{L - 1} {X}_{L - 1} & {W}_{L - 1} \\ {V}_{L - 1} {X}_{L - 1} & - {V}_{L - 1}\end{matrix} ] [ \begin{matrix}{c1}_{L - 1} \\ {c2}_{L - 1}\end{matrix} ] = [ \begin{matrix}I \\ {jY}_{L}\end{matrix} ] T , \qquad \text{(1.4.3)}$$

where, as above, the top and bottom halves of the vector equation provides matching of the electric field E_{y} and the magnetic field Hₓ, respectively. In contrast with equation (1.4.1), there is only a single term on the right since there is no incident radiation in the substrate 105.

Matrix equation (1.4.1), matrix equation (1.4.3), and the (L-1) matrix equations (1.4.2) can be combined 360 to provide a boundary-matched system matrix equation

$$[ \begin{matrix}- I & {W}_{1} & {W}_{1} {X}_{1} & 0 & 0 & ⋯ & ⋯ & \\ {jY}_{0} & {V}_{1} & - VX & 0 & 0 & ⋯ & ⋯ & \\ 0 & - {W}_{1} {X}_{1} & - {W}_{1} & {W}_{2} & {W}_{2} {X}_{2} & 0 & 0 & ⋯ \\ 0 & - {V}_{1} {X}_{1} & {V}_{1} & {V}_{2} & - {V}_{2} {X}_{2} & 0 & 0 & ⋯ \\ 0 & 0 & ⋰ & & ⋰ & & & ⋮ \\ 0 & 0 & & & & & & \\ & & ⋯ & & - {W}_{L - 1} {X}_{L - 1} & - {W}_{L - 1} & & I \\ & & & & - {V}_{L - 1} {X}_{L - 1} & {V}_{L - 1} & & {jY}_{L}\end{matrix} ] [ \begin{matrix}R \\ {c1}_{1} \\ {c2}_{1} \\ ⋮ \\ ⋮ \\ {c1}_{L - 1} \\ {c2}_{L - 1} \\ T\end{matrix} ] = [ \begin{matrix}{δ}_{i0} \\ j {δ}_{i0} {n}_{0} cos ( θ ) \\ 0 \\ ⋮ \\ \\ \\ ⋮ \\ 0\end{matrix} ] , \qquad \text{(1.4.4)}$$

and this boundary-matched system matrix equation (1.4.4) may be solved 365 to provide the reflectivity Rᵢ for each harmonic order i. (Alternatively, the partial-solution approach described in “Stable Implementation of the Rigorous Coupled-Wave Analysis for Surface-Relief Dielectric Gratings: Enhanced Transmittance Matrix Approach”, E. B. Grann and D. A. Pommet, J. Opt. Soc. Am. A, vol. 12, 1077-1086, May 1995, can be applied to calculate either the diffracted reflectivity R or the diffracted transmittance T.)

Rigorous Coupled-Wave Analysis for the TM Polarization

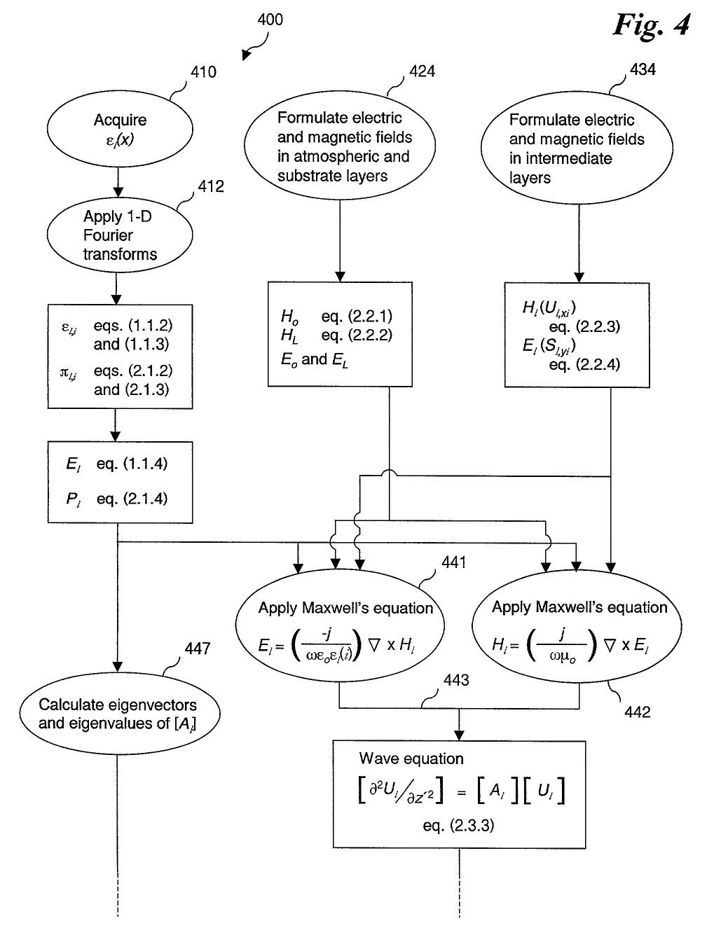

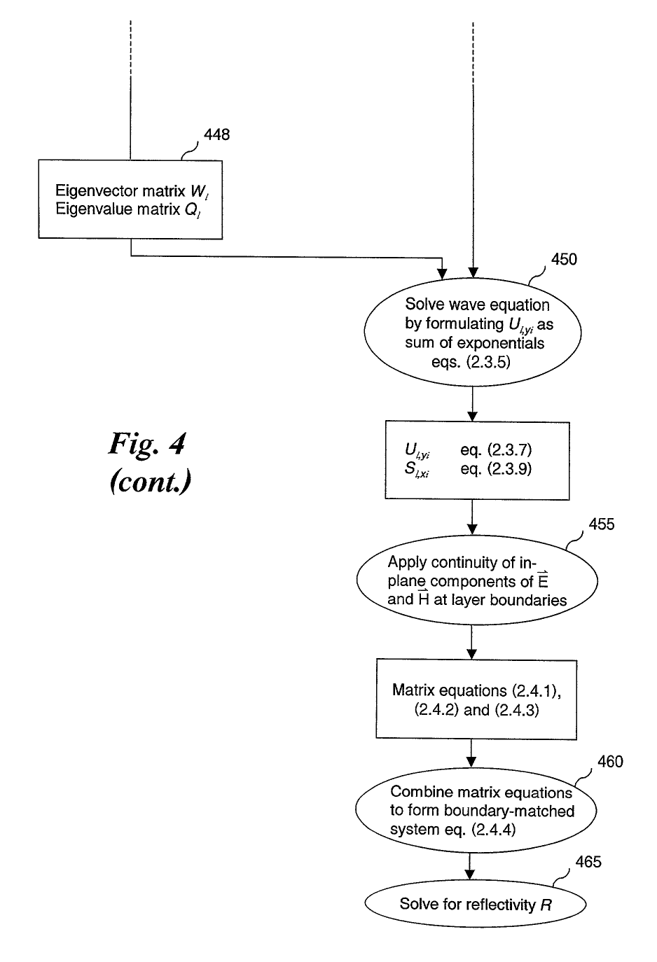

The method 400 of calculation for the diffracted reflectivity of TM-polarized incident electromagnetic radiation 131 shown in FIG. 4 parallels that 300 described above and shown in FIG. 3 for the diffracted reflectivity of TE-polarized incident electromagnetic radiation 131. The variables describing the geometry of the grating 100 and the geometry of the incident radiation 131 are as shown in FIGS. 1 and 2. However, for TM-polarized incident radiation 131 the electric field vector \vec{E} is in the plane of incidence 140, and the magnetic field vector \vec{H} is perpendicular to the plane of incidence 140. (The similarity in the TE- and TM-polarization RCWA calculations and the application of the present invention motivates the use of the term ‘electromagnetic field’ in the present specification to refer generically to either or both the electric field and/or the magnetic field of the electromagnetic radiation.)

As above, once the permittivity εₗ(x) is determined or acquired 410, the permittivity harmonics ε_{l,1} are determined 412 using Fourier transforms according to equations (1.1.2) and (1.1.3), and the permittivity harmonics matrix Eₗ is assembled as per equation (1.1.4). In the case of TM-polarized incident radiation 131, it has been found that the accuracy of the calculation may be improved by formulating the calculations using inverse-perrnittivity harmonics π_{l,1}, since this will involve the inversion of matrices which are less singular. In particular, the one-dimensional Fourier expansion 412 for the inverse of the permittivity εₗ(x) of the lth layer is given by

$$\frac{1}{{ϵ}_{l} ( x )} = {\sum }_{h = - ∞}^{∞} {π}_{l , h} exp ( j \frac{2 π h}{D} x ) . \qquad \text{(2.1.1)}$$

Therefore, via the inverse Fourier transform this provides

$${π}_{l , 0} = \frac{1}{{n}_{r}^{2}} \frac{{d}_{l}}{D} + \frac{1}{{n}_{0}^{2}} ( 1 - \frac{{d}_{l}}{D} ) , \qquad \text{(2.1.2)}$$

and for h not equal to zero,

$${π}_{l , h} = ( \frac{1}{{n}_{r}^{2}} - \frac{1}{{n}_{0}^{2}} ) \frac{sin ( π h \frac{{d}_{l}}{D} )}{π h} {ⅇ}^{- jπ h β / D} , \qquad \text{(2.1.3)}$$

where β is the x-offset of the center of the rectangular ridge slab 126.l from the origin. The inverse-permittivity harmonics matrix Pₗ is defined as

$${P}_{l} = [ \begin{matrix}{π}_{l , 0} & {π}_{l , - 1} & {π}_{l , - 2} & ⋯ & {π}_{l , - 2 o} \\ {π}_{l , 1} & {π}_{l , 0} & {π}_{l , - 1} & ⋯ & {π}_{l , - ( 2 o - 1 )} \\ {π}_{l , 2} & {π}_{l , 1} & {π}_{l , 0} & ⋯ & {π}_{l , - ( 2 o - 2 )} \\ ⋯ & ⋯ & ⋯ & ⋯ & ⋯ \\ {π}_{l , 2 o} & {π}_{l , ( 2 o - 1 )} & {π}_{l , ( 2 o - 2 )} & ⋯ & {π}_{l , 0}\end{matrix} ] , \qquad \text{(2.1.4)}$$

where 2o is the maximum harmonic order of the inverse permittivity π_{l,h} used in the calculation. As with the case of the TE polarization 300, for electromagnetic fields \vec{E} and \vec{H} calculated to order o it is necessary to use harmonic components of the permittivity ε^{l,h} and inverse permittivity π_{l,h} to order 2o.

In the atmospheric layer the magnetic field \vec{H} is formulated 424 a priori as a plane wave incoming at an angle of incidence θ, and a reflected wave which is a sum of plane waves having wave vectors (kₓₗ, k_{O,zl}) satisfing the Floquet condition, equation (1.2.6). In particular,

$${\vec{H}}_{0 , y} = exp ( - {jk}_{0} {n}_{0} ( sin θ x + cos θ z ) + {\sum }_{i} {R}_{i} exp ( - j ( {k}_{xi} x - {k}_{0 , zi} ) ) , \qquad ( 2.2 .1 )$$

where the term on the left of the right-hand side of the equation is the incoming plane wave, and Rᵢ is the magnitude of the ith component of the reflected wave. The wave vectors k_{O} and (kₓᵢ, k_{O,zl}) are given by equations (1.2.2), (1.2.3), and (1.2.4) above, and the magnetic field \vec{H} in the atmospheric layer l01 is generated from the electric field \vec{E} by Maxwell's equation (1.3.2). In the substrate layer l05 the magnetic field \vec{H} is formulated 424 as a transmitted wave which is a sum of plane waves where the wave vectors (kₓᵢ, k_{O,zl}) satisfy the Floquet condition, equation (1.2.6), i.e.,

$${\vec{H}}_{L , y} = {\sum }_{i} {T}_{i} exp ( - j ( {k}_{xi} x + {k}_{L , zi} ( z - {\sum }_{l = 1}^{L - 1} {t}_{l} ) ) ) , \qquad \text{(2.2.2)}$$

where k_{L,zl} is defined in equation (1.2.9). Again based on the Floquet condition, the magnetic field \vec{H}_{l,y} in the lth layer is formulated 434 as a plane wave expansion along the direction of periodicity, \hat{x}, i.e.,

$${\vec{H}}_{l , y} = {\sum }_{i} {U}_{l , yi} ( z ) exp ( - {jk}_{xi} x ) , \qquad ( 2.2 .3 )$$

where U_{l,yn} (z) is the z-dependent magnetic field harmonic amplitude for the lth layer and the ith harmonic. Similarly, the electric field \vec{E}_{l,x} in the lth layer is formulated 434 as a plane wave expansion along the direction of periodicity, i.e.,

$${\vec{E}}_{l , x} = {j ( \frac{{μ}_{0}}{{ϵ}_{0}} )}^{1 / 2} {\sum }_{i} {S}_{l , xi} ( z ) exp ( - {jk}_{xi} x ) , \qquad \text{(2.2.4)}$$

where S_{l,xl} (z) is the z-dependent electric field harmonic amplitude for the lth layer and the ith harmonic.

Substituting equations (2.2.3) and (2.2.4) into Maxwell's equation (1.3.2) provides 441 a first relationship between the electric and magnetic field harmonic amplitudes Sₗ and Uₗ for the lth layer:

$$\frac{\partial [ {U}_{l , yt} ]}{\partial {z}^{′}} = [ {E}_{l} ] [ {S}_{l , xi} ] . \qquad \text{(2.3.1)}$$

Similarly, substituting (2.2.3) and (2.2.4) into Maxwell's equation (1.3.1) provides 442 a second relationship between the electric and magnetic field harmonic amplitudes Sₗ and Uₗ for the lth layer:

$$\frac{\partial [ {S}_{l , xi} ]}{\partial {z}^{′}} = ( [ {K}_{x} ] [ {P}_{l} ] [ {K}_{x} ] - [ I ] ) [ {U}_{l , y} ] . \qquad ( 2.3 .2 )$$

where, as above, Kₓ is a diagonal matrix with the (i,i) element being equal to (kₓₗ/k_{O}). In contrast with equations (1.3.3) and (1.3.5) from the TE-polarization calculation, non-diagonal matrices in both equation (2.3.1) and equation (2.3.2) couple harmonic amplitudes Sₗ and Uₗ between harmonic orders.

Combining equations (2.3.1) and (2.3.2) provides a second-order differential wave equation

$$[ \frac{{\partial }^{2} {U}_{l , y}}{\partial {z}^{′2}} ] = \{ [ {E}_{l} ] ( [ {K}_{x} ] [ {P}_{l} ] [ {K}_{x} ] - [ I ] ) \} [ {U}_{l , y} ] , \qquad ( 2.3 .3 )$$

where [U_{l,y}] and [∂²U_{l,y}/∂z′²] are column vectors with indices running from −o to +o, and the permittivity harmonics [Eₗ] is defined above in equation (1.1.7), and z′=k_{O}z. The wave-vector matrix [Aₗ] for equation (2.3.3) is defined as

[Aₗ]=[Eₗ]([Kₓ][Pₗ][Kₓ]−[I]). (2.3.4)

If an infinite number of harmonics could be used, then the inverse of the permittivity harmonics matrix [Eₗ] would be equal to the inverse-permittivity harmonics matrix [P_{I}], and vice versa, i.e., [Eₗ]⁻¹=[Pₗ], and [Pₗ]⁻¹=[Eₗ]. However, the equality does not hold when a finite number o of harmonics is used, and for finite o the singularity of the matrices [Eₗ]⁻¹ and [Pₗ], and the singularity of the matrices [Pₗ]⁻¹ and [Eₗ], will generally differ. In fact, it has been found that the accuracy of RCWA calculations will vary depending on whether the wave-vector matrix [Aₗ] is defined as in equation (2.3.4), or

[Aₗ]=[Pₗ]⁻¹([Kₓ][Eₗ]⁻¹[Kₓ]−[I]), (2.3.5)

or

[Aₗ]=[Eₗ]([Kₓ][Eₗ]⁻¹[Kₓ]−[I]). (2.3.6)

It should also be understood that although the case where

[Aₗ]=[Pₗ]⁻¹([Kₓ][Pₗ][Kₓ]−[I]) (2.3.6′)

does not typically provide convergence which is as good as the formulations of equation (2.3.5) and (2.3.6), the present invention may also be applied to the formulation of equation (2.3.6′).

Regardless of which of the three formulations, equations (2.3.4), (2.3.5) or (2.3.6), for the wave-vector matrix [Aₗ] is used, the solution of equation (2.3.3) is performed by writing 450 the homogeneous solution for the magnetic field harmonic amplitude Uₗ as an expansion in pairs of exponentials, i.e.,

$${U}_{l , yi} ( z ) = {\sum }_{m = 1}^{2 o + 1} {w}_{l , i , m} [ {c1}_{l , m} exp ( - {k}_{0} {q}_{l , m} z ) + ( {c2}_{l , m} ( z - {t}_{l} ) ) ] . \qquad ( 2.3 .7 )$$

since its functional form is maintained upon second-order differentiation by z′, and equation (2.3.3) becomes an eigenequation. Solution 447 of the eigenequation

[Aₗ][Wₗ]=[τₗ][Wₗ], (2.3.8)

provides 448 an eigenvector matrix [Wₗ] formed from the eigenvectors w_{l,1} of the wave-vector matrix [Aₗ], and a diagonal eigenvalue matrix [τₗ] formed from the eigenvalues τ_{l,i} of the wave-vector matrix [Aₗ]. A diagonal root-eigenvalue matrix [Qₗ] is formed of diagonal entries q_{l,i} which are the positive real portion of the square roots of the eigenvalues τ_{l,i}. The constants c1 and c2 of equation (2.3.7) are, as yet, undetermined.

By applying equation (1.3.3) to equation (2.3.5) it is found that

$${S}_{l , xi} ( z ) = {\sum }_{m = 1}^{2 o + 1} {v}_{l , i , m} [ - {c1}_{l , m} exp ( - {k}_{0} {q}_{l , m} z ) + {c2}_{l , m} exp ( {k}_{0} {q}_{l , m} ( z - {t}_{l} ) ) ] \qquad ( 2.3 .9 )$$

where the vectors v_{l,1} form a matrix [Vₗ] defined as

[V]=[E]⁻¹[W][Q] when [A] is defined as in equation (2.3.4), (2.3.10)

[V]=[P][W][Q] when [A] is defined as in equation (2.3.5), (2.3.11)

[V]=[E]⁻¹[W][Q] when [A] is defined as in equation (2.3.6). (2.3.12)

The formulations of equations (2.3.5), (2.3.6), (2.3.11) and (2.3.12) typically has improved convergence performance (see P. Lalanne and G. M. Morris, “Highly Improved Convergence of the Coupled-Wave Method for TM Polarization”, J. Opt. Soc. Am. A, 779-784, 1996; and L. Li and C. Haggans, “Convergence of the coupled-wave method for metallic lamellar diffraction gratings”, J. Opt. Soc. Am. A, 1184-1189, June 1993) relative to the formulation of equations (2.3.4) and (2.3.11) (see M. G. Moharam and T. K. Gaylord, “Rigorous Coupled-Wave Analysis of Planar-Grating Diffraction”, J. Opt. Soc. Am., vol. 71, 811-818, July 1981).

The constants c1 and c2 in the homogeneous solutions of equations (2.3.7) and (2.3.9) are determined by applying 455 the requirement that the tangential electric and tangential magnetic fields be continuous at the boundary between each pair of adjacent layers 125.l/125.(l+1), when the materials in each layer non-conductive. (The calculation of the present specification is straightforwardly modified to circumstances involving conductive materials, and the application of the method of the present invention to periodic gratings which include conductive materials is considered to be within the scope of the present invention. At the boundary between the atmospheric layer 101 and the first layer l25.1, continuity of the magnetic field H_{y} and the electric field Eₓ requires

$$[ \begin{matrix}{δ}_{i 0} \\ j cos ( θ ) {δ}_{i 0} / {n}_{0}\end{matrix} ] + [ \begin{matrix}I \\ - {jZ}_{0}\end{matrix} ] R = [ \begin{matrix}{W}_{l} & {W}_{l} {X}_{l} \\ {V}_{l} & - {V}_{l} {X}_{l}\end{matrix} ] [ \begin{matrix}{c1}_{l} \\ {c2}_{l}\end{matrix} ] \qquad ( 2.4 .1 )$$

where Z_{O} is a diagonal matrix with entries (k_{O,zl}/n_{O}²k_{O}), Xₗ is a diagonal matrix with elements exp(−k_{O} q_{l,m} tₗ), the top half of the vector equation provides matching of the magnetic field H_{y} across the layer boundary, the bottom half of the vector equation provides matching of the electric field Eₓ across the layer boundary, the vector on the far left is the contribution from the incoming radiation 131 in the atmospheric layer l01, the second vector on the left is the contribution from the reflected radiation 132 in the atmospheric layer l01, and the portion on the right represents the fields H_{y} and Eₓ in the first layer l25.1.

At the boundary between adjacent intermediate layers 125.l and 125.(l+1), continuity of the electric field E_{y} and the magnetic field Hₓ requires

$$[ \begin{matrix}{W}_{l - 1} {X}_{l - 1} & {W}_{l - 1} \\ {W}_{l - 1} {X}_{l - 1} & - {V}_{l - 1}\end{matrix} ] [ \begin{matrix}{c1}_{l - 1} \\ {c2}_{l - 1}\end{matrix} ] = [ \begin{matrix}{W}_{l} & {W}_{l} {X}_{l} \\ {V}_{l} & - {V}_{l} {X}_{l}\end{matrix} ] [ \begin{matrix}{c1}_{l} \\ {c2}_{l}\end{matrix} ] \qquad ( 2.4 .2 )$$

where the top and bottom halves of the vector equation provides matching of the magnetic field H_{y} and the electric field Eₓ, respectively, across the layer boundary.

At the boundary between the (L-1)th layer l25.(L-1) and the substrate layer 105, continuity of the electric field E_{y} and the magnetic field Hₓ requires

$$[ \begin{matrix}{W}_{L - 1} {X}_{L - 1} & {W}_{L - 1} \\ {V}_{L - 1} {X}_{L - 1} & - {V}_{L - 1}\end{matrix} ] [ \begin{matrix}{c1}_{L - 1} \\ {c2}_{L - 2}\end{matrix} ] = [ \begin{matrix}I \\ {jZ}_{L}\end{matrix} ] T , \qquad ( 2.4 .3 )$$

where, as above, the top and bottom halves of the vector equation provides matching of the magnetic field H_{y} and the electric field Eₓ, respectively. In contrast with equation (2.4.1), there is only a single term on the right in equation (2.4.3) since there is no incident radiation in the substrate 105.

Matrix equation (2.4.1), matrix equation (2.4.3), and the (L-1) matrix equations (2.4.2) can be combined 460 to provide a boundary-matched system matrix equation

$$[ \begin{matrix}- I & {W}_{1} & {W}_{1} {X}_{1} & 0 & 0 & ⋯ & & \\ {jZ}_{0} & {V}_{1} & - VX & 0 & 0 & ⋯ & & \\ 0 & - {W}_{1} {X}_{1} & - {W}_{1} & {W}_{2} & {W}_{2} {X}_{2} & 0 & 0 & ⋯ \\ 0 & - {V}_{1} {X}_{1} & {V}_{1} & {V}_{2} & - {V}_{2} {X}_{2} & 0 & 0 & ⋯ \\ 0 & 0 & ⋰ & & ⋰ & & ⋮ & \\ 0 & 0 & & & & & & \\ & & ⋯ & & - {W}_{L - 1} {X}_{L - 1} & - {W}_{L - 1} & I & \\ & & & & - {V}_{L - 1} {X}_{L - 1} & {V}_{L - 1} & {jZ}_{L} & \end{matrix} ] [ \begin{matrix}R \\ {c1}_{1} \\ {c2}_{1} \\ ⋮ \\ ⋮ \\ {c1}_{L - 1} \\ {c2}_{L - 1} \\ T\end{matrix} ] = \\ [ \begin{matrix}{δ}_{i 0} \\ {jδ}_{i 0} cos ( θ ) / {n}_{0} \\ 0 \\ ⋮ \\ \\ \\ ⋮ \\ 0\end{matrix} ] ; \qquad ( 2.4 .4 )$$

and the boundary-matched system matrix equation (2.4.4) may be solved 465 to provide the reflectivity R for each harmonic order i. (Alternatively, the partial-solution approach described in “Stable Implementation of the Rigorous Coupled-Wave Analysis for Surface-Relief Dielectric Gratings: Enhanced Transmittance Matrix Approach”, E. B. Grann and D. A. Pommet, J. Opt. Soc. Am. A, vol. 12, 1077-1086, May 1995, can be applied to calculate either the diffracted reflectivity R or the diffracted transmittance T.)

Solving for the Diffracted Reflectivity

The matrix on the left in boundary-matched system matrix equations (1.4.4) and (2.4.4) is a square non-Hermetian complex matrix which is sparse (i.e., most of its 4. entries are zero), and is of constant block construction (i.e., it is an array of sub-matrices of uniform size). According to the preferred embodiment of the present invention, and as is well-known in the art of the solution of matrix equations, the matrix is stored using the constant block compressed sparse row data structure (BSR) method (see S. Carney, M. Heroux, G. Li, R. Pozo, K. Remington and K. Wu, “A Revised Proposal for a Sparse BLAS Toolkit,” http://www.netlib.org, 1996). In particular, for a matrix composed of a square array of square sub-matrices, the BSR method uses five descriptors:

B_LDA is the dimension of the array of sub-matrices;

O is the dimension of the sub-matrices;

VAL is a vector of the non-zero sub-matrices starting from the leftmost non-zero matrix in the top row (assuming that there is a non-zero matrix in the top row), and continuing on from left to right, and top to bottom, to the rightmost non-zero matrix in the bottom row (assuming that there is a non-zero matrix in the bottom row).

COL_IND is a vector of the column indices of the sub-matrices in the VAL vector; and

ROW_PTR is a vector of pointers to those sub-matrices in VAL which are the first non-zero sub-matrices in each row.

For example, for the left-hand matrix of equation (1.4.4), B_LDA has a value of 2L, O has a value of 2o+1, the entries of VAL are (−I, Wₗ, WₗXₗ, jY_{O}, Vₗ, −VₗXₗ, −WₗXₗ, −Wₗ, W₂, W₂X₂, −VₗXₗ, V₁, V₂ . . . ), the entries of COL_IND are (1, 2, 3, 1, 2, 3, 2, 3, 4, 5, 2, 3, 4, 5, . . . ), and the entries of ROW_PTR are (1, 4, 7, 11, . . . ).

According to the preferred embodiment of the present invention, and as is well-known in the art of the solution of matrix equations, the squareness and sparseness of the left-hand matrices of equations (1.4.4) and (2.4.4) are used to advantage by solving equations (1.4.4) and (2.4.4) using the Blocked Gaussian Elimination (BGE) algorithm. The BGE algorithm is derived from the standard Gaussian Elimination algorithm (see, for example, Numerical Recipes, W. H. Press, B. P. Flannery, S. A. Teukolsky, and W. T. Vetterling, Cambridge University Press, Cambridge, 1986, pp. 29-38) by the substitution of sub-matrices for scalars. According to the Gaussian Elimination method, the left-hand matrix of equation (1.4.4) or (2.4.4) is decomposed into the product of a lower triangular matrix [L], and an upper triangular matrix [U], to provide an equation of the form

[L][U][x]=[b], (3.1.1)

and then the two triangular systems [U] [x]=[y] and [L] [y]=[b] are solved to obtain the solution [x]=[U]⁻¹[L]⁻¹[b], where, as per equations (1.4.4) and (2.4.4), [x ] includes the diffracted reflectivity R.

Caching of Permittivity Harmonics and Eigensolutions

As presented above, the calculation of the diffraction of incident TE-polarized or TM-polarized incident radiation 131 from a periodic grating involves the generation of a boundary-matched system matrix equation (1.4.4) or (2.4.4), respectively, and its solution. In understanding the advantages of the present invention it is important to appreciate that the most computationally expensive portion of the processes of FIGS. 3 and 4 is the solution 347 and 447 for the eigenvectors w_{l,1} and eigenvalues τ_{l,i} of wave-vector matrix [Aₗ] of equation (1.3.7), (2.3.4), (2.3.5) or (2.3.6). The accuracy of the calculation of the eigenvectors w_{l,i} and eigenvalues τ_{l,i} is dependent on the number of orders o utilized. As the number of orders o is increased, the computation time for solving the eigensystem increases exponentially with o. In contrast, the solution of equations (1.4.4) and (2.4.4), as described in Section 3 above, scales as l³ o³. When performed in a typical computing environment with o=9 harmonic orders, the calculation of the eigenvectors and eigenvalues can take more than 85% of the total computation time.

The method of the present invention is implemented on a computer system 800 which in its simplest form consists of information input/output (I/O) equipment 805, which is interfaced to a computer 810 which includes a central processing unit (CPU) 815 and a memory 820. The I/O equipment 805 will typically include a keyboard 802 and mouse 804 for the input of information, and a cathode ray tube 801 and printer 803 for the output of information. Many variations on this simple computer system 800 are to be considered within the scope of the present invention, including systems with multiple I/O devices, multiple processors within a single computer, multiple computers connected by Internet linkages, multiple computers connected by local area networks, etc. For instance, the method of the present invention may be applied to any of the systems described in provisional patent application serial No. 60/178,540, filed Jan. 26, 2000, entitled Profiler Business Model, by the present inventors, and provisional patent application serial No. 60/209,424, filed Jun. 2, 2000, entitled Profiler Business Model, by the present inventors, both of which are incorporated herein by reference.

According to the method and apparatus of the present invention, portions of the analysis of FIG. 3 are pre-computed and cached, thereby reducing the computation time required to calculate the diffracted reflectivity produced by a periodic grating. Briefly, the pre-computation and caching portion of the present invention consists of:

pre-computation and caching (i.e., storage in a look-up table) of the permittivity ε_{μ}(x), the harmonic components ε_{μ,i} of the permittivity ε_{μ}(x) and the permittivity harmonics matrix [E_{μ}], and/or the inverse-permittivity harmonics π_{μi} and the inverse-permittivity harmonics matrix [P_{μ}] for a sampling region {μ} of layer-property values;

pre-computation and caching of the wave-vector matrix [A_{μ,κ}] for the sampling region {μ} of layer-property values and a sampling region {κ} of incident-radiation values; and

pre-computation and caching of eigenvectors w_{μ,κ,m} and eigenvalues τ_{μ,κ,m} of the wave-vector matrix [A_{μ,κ}] to form an eigenvector matrix [W_{μ,κ}], a root-eigenvalue matrix [Q_{μ,κ}], and a compound matrix [V_{μ,κ}], respectively, for a master sampling region {μ, κ} formed from the combination of the layer-property sampling region {μ} and the incident-radiation sampling region {κ};

Briefly, the use of the master sampling region {μ, κ} of pre-computed and cached eigenvector matrices [W_{μ,κ}], root-eigenvalue matrices [Q_{μ,κ}], and product matrices [V_{μ,κ}] to calculate the diffraction spectrum from a periodic grating consists of the steps of:

construction of matrix equation (1.4.4) or (2.4.4) by retrieval of cached eigenvector matrices [W_{μ,κ}], root-eigenvalue matrices [Q_{μ,κ}], and product matrices [V_{μ,κ}] from the master sampling region {μ,78 } corresponding to the layers 125 of the grating 100 under consideration; and

solution of the matrix equation (1.4.4) or (2.4.4) to determine the diffracted reflectivity Rᵢ for each harmonic order i.

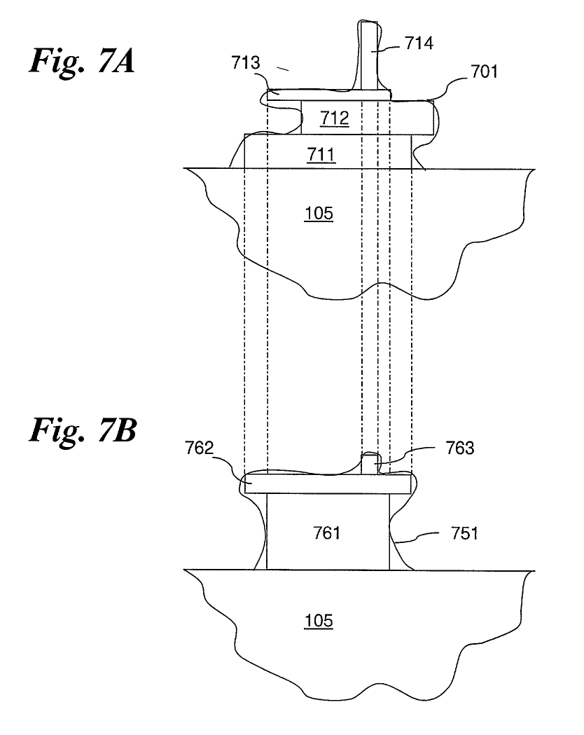

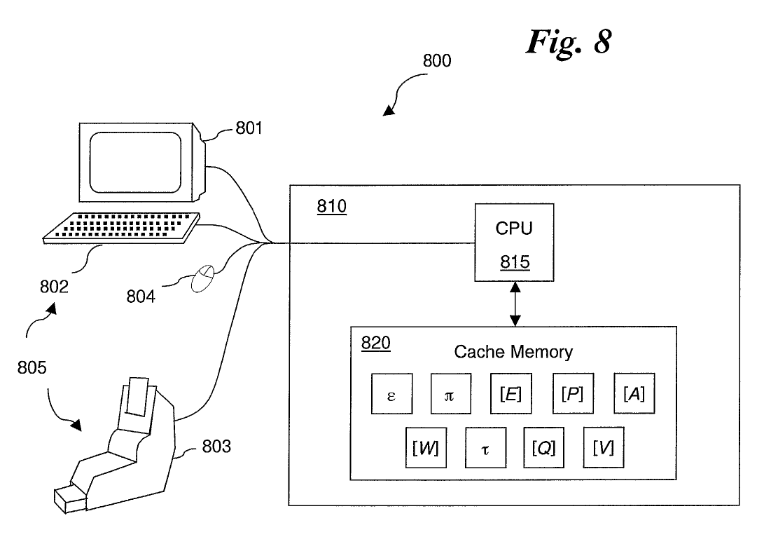

The method of the present invention is illustrated by consideration of the exemplary ridge profiles 701 and 751 shown in cross-section in FIGS. 7A and 7B, respectively. The profile 701 of FIG. 7A is approximated by four slabs 711, 712, 713 and 714 of rectangular cross-section. Similarly, the profile 751 of FIG. 7B is approximated by three slabs 751, 752, and 753 of rectangular cross-section. The two exemplary ridge profiles 701 and 751 are each part of an exemplary periodic grating (other ridges not shown) which have the same grating period D, angle θ of incidence of the radiation 131, and radiation wavelength λ. Furthermore, slabs 713 and 761 have the same ridge slab width d, x-offset β, and index of refraction nᵣ, and the index of refraction n_{O} of the atmospheric material between the ridges 701 and 751 is the same. Similarly, slabs 711 and 762 have the same ridge slab width d, x-offset β, and index of refraction nᵣ, and slabs 714 and 763 have the same ridge slab width d, x-offset β, and index of refraction nᵣ. However, it should be noted that slabs 714 and 763 do not have the same thicknesses t, nor do slabs 713 and 761 or slabs 712 and 762 have the same thicknesses t. It is important to note that thickness t is not a parameter upon which the wave-vector matrix [A] is dependent, although thickness t does describe an intra-layer property.

In performing an RCWA calculation for the diffracted reflectivity from grating composed of profiles 701, the eigenvector matrices [W], the root-eigenvalue matrices [Q], and the compound eigensystem matrices [V] are computed for rectangular slabs 711, 712, 713, and 714. According to the present invention it is noted that the eigenvector matrices [W], the root-eigenvalue matrices [Q], and the compound eigensystem matrices [V] for slabs 761, 762 and 763 are the same as the eigenvector matrices [W], the root-eigenvalue matrices [Q], and the compound eigensystem matrices [V] for slabs 713, 711 and 714, respectively, since the wave-vector matrices [A] are the same for slabs 711 and 762, 713 and 761, and 714 and 763. Therefore, caching and retrieval of the eigensystem matrices [W], [Q], and [V] for slabs 713, 711 and 714 would prevent the need for recalculation of eigensystem matrices [W], [Q], and [V] for slabs 761, 762 and 763, and reduce the computation time. More broadly, the pre-calculation and caching of eigensystem matrices [W], [Q], and [V] for useful ranges and samplings of intra-layer parameters and incident-radiation parameters will greatly reduce the computation time necessary to perform RCWA calculations.

Fundamental to the method and apparatus of the present invention is the fact that the permittivity harmonics ε_{l,1} and the inverse permittivity harmonics π_{l,1} are only dependent on the intra-layer parameters: the index of refraction of the ridges nᵣ, the index of refraction of the atmospheric material n_{O}, the pitch D, the ridge slab width d, and the x-offset β, as can be seen from equations (1.1.2), (1.1.3), (2.1.2) and (2.1.3). As shown in the flowchart of FIG. 5, the system 600 of the present invention begins with the determination 605 of the ranges n_{r,min} to n_{r,max}, n_{O,min} to n_{O,max}, Dₘᵢₙ to Dₘₐₓ, dₘᵢₙ to dₘₐₓ,

and βₘᵢₙ to βₘₐₓ, and increments δnᵣ, δn_{O}, δD, δd, and δβ for the layer-property parameters, i.e., the index of refraction of the ridges nᵣ, the index of refraction of the atmospheric material n_{O}, the pitch D, the ridge slab width d, the x-offset β, as well as the determination 605 of the maximum harmonic order o. This information is forwarded from an I/O device 805 to the CPU 815. Typically, when applied to periodic gratings produced by semiconductor fabrication techniques, the ranges n_{r,min} to nᵣₘₐₓ, n_{O,min} to n_{O,max}, Dₘᵢₙ to Dₘₐₓ, dₘᵢₙ to dₘₐₓ, and βₘᵢₙ to βₘₐₓ are determined based on knowledge and expectations regarding the fabrication materials, the fabrication process parameters, and other measurements taken of the periodic grating 100 or related structures. Similarly, when matching calculated diffraction spectra to a measured diffraction spectrum to determine the dimensions of the periodic grating that created the measured diffraction spectrum, the increments δnᵣ, δn_{O}, δD, δd, and δβ, and maximum harmonic order o, are chosen based on the resolution to which the layer-property parameters nᵣ, n_{O}, D, d and β are to be determined. The layer-property parameter ranges n_{r,min} to n_{r,max}, n_{O,min} to n_{O,max}, Dₘᵢₙ to Dₘₐₓ, dₘᵢₙ to dₘₐₓ, and βₘᵢₙ to βₘₐₓ, and increments δnᵣ, δn_{O}, δD, and δd, and δβ define a five-dimensional layer-property caching grid {μ}. More specifically, the caching grid {μ} consists of layer-property points with the n, coordinates being {n_{r,min}, n_{r,min}+δnᵣ, n_{r,min}+2δnᵣ, . . . , n_{r,max}−2δnᵣ, n_{r,max}−δnᵣ, n_{r,max}}, the n_{O} coordinates being {n_{O,min}, n_{O,min}+δn_{O}, n_{O,min}+2δn_{O}, . . . , n_{O,max}−2δn_{O}, n_{O,max}−δn_{O}, n_{O,max}}, the D coordinates being {Dₘᵢₙ, Dₘᵢₙ+δD, Dₘᵢₙ+2δD, . . . , Dₘₐₓ−2δD, Dₘₐₓ−δD, Dₘₐₓ}, the d coordinates being {dₘᵢₙ, dₘᵢₙ+δd, dₘᵢₙ+2δd, . . . , dₘₐₓ−2δd, dₘₐₓ−δd, dₘₐₓ}, and the β coordinates being {βₘᵢₙ, βₘᵢₙ+δβ. βₘᵢₙ+2δβ, . . . βₘₐₓ−2δβ, βₘₐₓ−δβ, βₘₐₓ}. In other words, the layer-property caching grid {μ} is defined as a union of five-dimensional coordinates as follows:

$$\{ μ \} = {⋃}_{i , j , k , l , m} ( {n}_{r , min} + i δ {n}_{r} , {n}_{0 , min} + j δ {n}_{0} , {D}_{min} + k δ D , {d}_{min} + l δ d , {β}_{min} + m δ β ) , \qquad ( 4.1 .1 )$$

where i, j, k, l and m are integers with value ranges of

0≦i≦(n_{r,max}−n_{r,min})/δnᵣ, (4.1.2a)

0≦j≦(n_{O,max}−n_{O,min})/δn_{O}, (4.1.2b)

0≦k≦(Dₘₐₓ−Dₘᵢₙ)/δD, (4.1.2c)

0≦l≦(dₘₐₓ−dₘᵢₙ)/δd, (4.1.2d)

and

0≦m≦(βₘₐₓ−βₘᵢₙ)/δβ. (4.1.2.e)

It should be noted that the variable l in equations (4.1.1) and (4.1.2d) is not to be confused with the layer number l used in many of the equations above. Furthermore, it may be noted that the layer subscript, 1, is not used in describing the layer-property parameters nrl no, D, d, and D used in the layer-property caching grid {μ} because each particular point μⱼ in the layer-property caching grid {μ} may correspond to none, one, more than one, or even all of the layers of a particular periodic grating 100. It should also be understood that the layer-property parameter region need not be a hyper-rectangle, and the layer-property parameter region need not be sampled using a grid. For instance, the sampling of the layer-property parameter region may be performed using a stochastic sampling method. Furthermore, the sampling density of the layer-property parameter region need not be uniform. For instance, the sampling density may decrease near the boundaries of the layer-property parameter region if layers 125 described by layer properties near the boundaries are less likely to occur.

As shown in FIG. 5, for each point μⱼ in the layer-property caching grid {μ} the “required” permittivity harmonics \overline{εₗ} are calculated 410 by CPU 815 and cached 415 in memory 820, and the “required” permittivity harmonics matrices [symbol] are compiled from the cached required permittivity harmonics \overline{εₗ} and cached 415′ in memory 820. For RCWA analyses of TE-polarized incident radiation 131, or RCWA analyses of TM-polarized incident radiation 131 according to the formulation of equations (2.3.6) and (2.3.12), the required permittivity harmonics \overline{εₗ} are the permittivity harmonics εᵢ calculated 410 according to equations (1.1.2) and (1.1.3), and the required permittivity harmonics matrix [symbol] is the permittivity harmonics matrix [E] formed as per equation (1.1.4). Similarly, for RCWA analyses of TM-polarized incident radiation 131 according to the formulation of equations (2.3.5) and (2.3.11) or equations (2.3.4) and (2.3.10), the required permittivity harmonics \overline{εₗ} are the permittivity harmonics ε_{I} calculated 410 according to equations (1.1.2) and (1.1.3) and the inverse-permittivity harmonics πₗ calculated 410 according to equations (2.1.2) and (2.1.3), and the required permittivity harmonics matrices E are the permittivity harmonics matrix [E] formed from the permittivity harmonics εᵢ as per equation (1.1.4) and the inverse-permittivity harmonics matrix [P] formed from the inverse-permittivity harmonics iri as per equation (2.1.4).

As per equations (1.3.7), (2.3.4), (2.3.5) and (2.3.6), the wave-vector matrix [A] is dependent on the required permittivity harmonics matrices E and the matrix [Kₓ]. eThe matrix [Kₓ], in addition to being dependent on layer-property parameters (i.e., the atmospheric index of refraction n_{O} and pitch D), is dependent on incident-radiation parameters, i.e., the angle of incidence θ and the wavelength λ of the incident radiation 131. Therefore, as shown in the flowchart of FIG. 5, according to the method of the present invention, ranges θₘᵢₙ to θₘₐₓ and λₘᵢₙ to λₘₐₓ, and increments δθ and δλ are determined 617 for the incidence angle θ and wavelength λ, and forwarded from an I/O device 805 to the CPU 815. The incident-radiation caching grid {κ} is defined as a union of two-dimensional coordinates as follows:

$$\{ κ \} = {⋃}_{n , o} ( {θ}_{min} + n δ θ , {λ}_{min} + o δ λ \qquad ( 4.1 .3 )$$

where n and o are integers with value ranges of

$$\begin{matrix}0 \leq n \leq ( {θ}_{max} - {θ}_{min} ) / δ θ , & ( 4.1 .4 a ) \\ 0 \leq o \leq ( {λ}_{max} - {λ}_{min} ) / δ λ . & ( 4.1 .4 b )\end{matrix}$$

(The variable o in equations (4.1.3) and (4.1.4b) is not to be confused with the maximum harmonic order o used in many of the equations above.) Furthermore, the master caching grid {μ, κ} is defined as a union of coordinates as follows:

$$\{ μ , κ \} = {⋃}_{i , j , k , l , m} ( {n}_{r , min} + i δ {n}_{r} , {n}_{0 , min} + j δ {n}_{0} , {D}_{min} + k δ D , {d}_{min} + l δ d , {β}_{min} + m δβ , {θ}_{min} + δθ , {λ}_{min} + m δλ )$$

where i, j, k, l, m, n and o satisfy equations (4.1.2a), (4.1.2b), (4.1.2c), (4.1.2d), (4.1.4a) and (4.1.4b). Typically, the ranges θₘᵢₙ to θₘₐₓ and λₘᵢₙ to λₘₐₓ are determined 617 based on knowledge and expectations regarding the apparatus (not shown) for generation of the incident radiation 131 and the apparatus (not shown) for measurement of the diffracted radiation 132. Similarly, the increments δθ and δλ are determined 617 based on the resolution to which the layer-property parameters nᵣ, n_{O}, D, d, and β are to be determined, and/or the resolution to which the incident-radiation parameters θ and λ can be determined. For instance, the increments δnᵣ, δn_{O}, δD, δd, δβ, δθ, and δλ may be determined as per the method disclosed in the provisional patent application entitled Generation of a Library of Periodic Grating Diffraction Spectra, filed Sep. 15, 2000 by the same inventors, and incorporated herein by reference. For each point in the master caching grid {μ, κ}, the matrix [A] is calculated 620 by the CPU 815 according to equation (1.3.7), (2.3.4), (2.3.5) or (2.3.6) and cached 425.

It should be noted that if any of the layer-property parameters nᵣ, n_{O}, D, d, and β, or any of the incident-radiation parameters θ and λ, are known to sufficient accuracy, then a single value, rather than a range of values, of the variable may be used, and the dimensionality of the master caching grid {μ, κ} is effectively reduced. It should also be understood that incident-radiation parameter region need not be a hyper-rectangle, and the incident-radiation parameter region need not be sampled using a grid. For instance, the sampling of the incident-radiation parameter region may be performed using a stochastic sampling method. Furthermore, the sampling density of the incident-radiation parameter region need not be uniform. For instance, the sampling density may decrease near the boundaries of the the incident-radiation parameter region if radiation-incidence circumstances near the boundaries are less likely to occur.

Since the wave-matrix matrix [A] is only dependent on intra-layer parameters (index of refraction of the ridges nᵣ, index of refraction of the atmospheric material n_{O}, pitch D, ridge slab width d, x-offset β) and incident-radiation parameters (angle of incidence θ of the incident radiation 131, wavelength λ of the incident radiation 131), it follows that the eigenvector matrix [W] and the root-eigenvalue matrix [Q] are also only dependent on the layer-property parameters nᵣ, n_{O}, D, d, and β, and the incident-radiation parameters θ and λ. According to the preferred embodiment of the present invention, the eigenvector matrix [W] and its root-eigenvalue matrix [Q] are calculated 647 by the CPU 815 and cached 648 in memory 820 for each point in the master caching grid {μ, κ}. The calculation 647 of the eigenvector matrices [W] and the root-eigenvalue matrices [Q] can be performed by the CPU 815 using a standard eigensystem solution method, such as singular value decomposition (see Chapter 2 of Numerical Recipes, W. H. Press, B. P. Glannery, S. A. Teukolsky and W. T. Vetterling, Cambridge University Press, 1986). The matrix [V], where [V]=[W][Q], is then calculated 457 by the CPU 815 and cached 658 in memory 820.

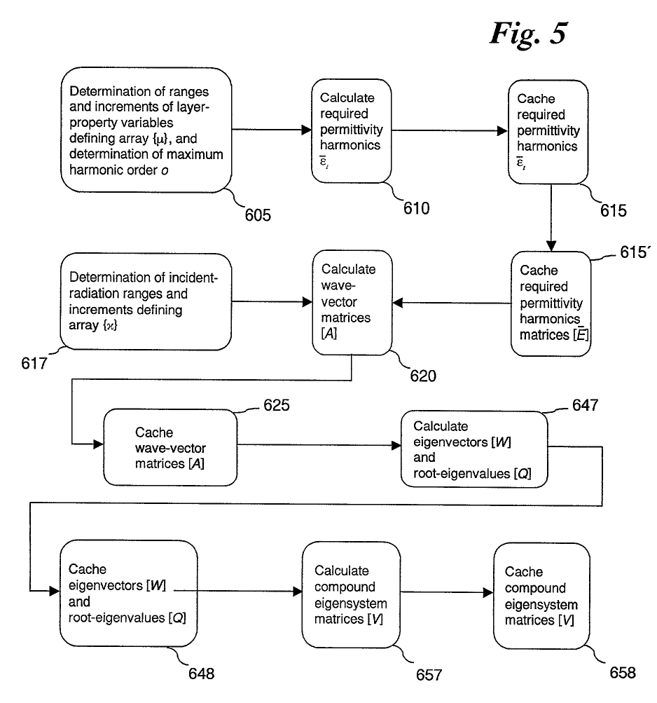

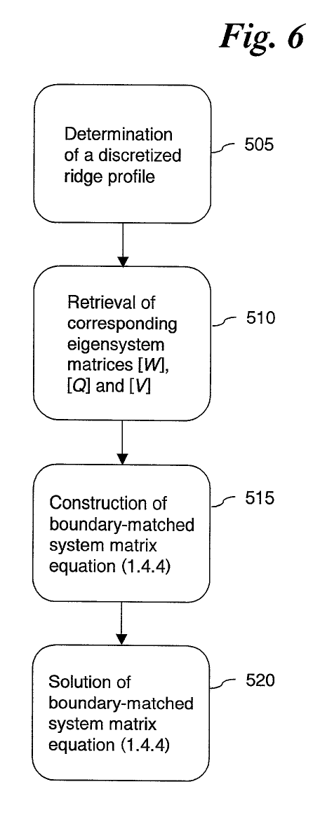

The method of use of the pre-computed and cached eigenvector matrices [W_{μ,κ}] root-eigenvalue matrices [Q_{μ,κ}], and product matrices [V_{μ,κ}] according to the present invention is shown in FIG. 6. Use of the cached eigensystem matrices [W_{μ,κ}], [Q_{μ,κ}], and [V_{μκ}] begins by a determination 505 of the parameters describing a discretized ridge profile. In particular, the intra-layer parameters (i.e., index of refraction of the ridges nᵣ, the index of refraction of the atmospheric material n_{O}, the pitch D, the ridge slab width d, and the x-offset β) for each layer, and the incident-radiation parameters (i e., the angle of incidence θ and the wavelength λ of the incident radiation) are determined 505 and forwarded via an I/O device 805 to the CPU 815. The determination 505 of the discretized ridge profile may be a step in another process, such as a process for determining the ridge profile corresponding to a measured diffraction spectrum produced by a periodic grating.

Once the intra-layer and incident-radiation parameters are determined 505, the cached eigensystem matrices [W_{μ,κ}], [Q_{μ,κ}], and [V_{μ,κ}] for those intra-layer and incident-radiation parameters are retrieved 510 from memory 820 for use by the CPU 815 in constructing 515 the boundary-matched system matrix equation (1.4.4) or (2.4.4). The CPU 815 then solves 520 the boundary-matched system matrix equation (1.4.4) or (2.4.4) for the reflectivity Rₗ of each harmonic order from −o to +o and each wavelength λ of interest, and forwards the results to an output device 805 such as the cathode ray tube 801 or printer 803.

It should be noted that although the invention has been described in term of a method, as per FIGS. 5 and 6, the invention may alternatively be viewed as an apparatus. For instance, the invention may implemented in hardware. In such case, the method flowchart of FIG. 5 would be adapted to the description of an apparatus by: replacement in step 605 of “Determination of ranges and increments of layer-property variables defining array {μ}, and means for determination of maximum harmonic order o” with “Means for determination of ranges and increments of layer-property variables defining array {μ}, and means for determination of maximum harmonic order o”; the replacement in step 617 of “Determination of incident-radiation ranges and increments defining array {78 }” with “Means for determination of incident-radiation ranges and increments defining array {κ}”; the replacement in steps 610, 620, 647, and 657 of “Calculate . . . ” with “Means for Calculating . . . ”; and the replacement in steps 615, 615′, 625, 648 and 658 of “Cache . . . ” with “Cache of . . . ”.

In the same fashion, the method flowchart of FIG. 6 would be adapted to the description of an apparatus by: replacement of “Determination . . . ” in step 505 with “Means for determination . . . ”; replacement of “Retrieval . . . ” in step 510 with “Means for retrieval . . . ”; replacement of “Construction . . . ” in step 515 with “Means for construction . . . ”; and replacement of “Solution . . . ” in step 520 with “Means for solution . . . ”.

It should also be understood that the present invention is also applicable to off-axis or conical incident radiation 13 1 (i.e., the case where φ≢0 and the plane of incidence 140 is not aligned with the direction of periodicity, \hat{x}, of the grating). The above exposition is straightforwardly adapted to the off-axis case since, as can be seen in “Rigorous Coupled-Wave Analysis of Planar-Grating Diffraction,” M. G. Moharam and T. K. Gaylord, J. Opt. Soc. Am., vol. 71, 811-818, July 1981, the differential equations for the electromagnetic fields in each layer have homogeneous solutions with coefficients and factors that are only dependent on intra-layer parameters and incident-radiation parameters. As with the case of on-axis incidence, intra-layer calculations are pre-calculated and cached. In computing the diffracted reflectivity from a periodic grating, cached calculation results for intra-layer parameters corresponding to the layers of the periodic grating, and incident-radiation parameters corresponding to the radiation incident on the periodic grating, are retrieved for use in constructing a boundary-matched system matrix equation in a manner analogous to that described above.

The foregoing descriptions of specific embodiments of the present invention have been presented for purposes of illustration and description. They are not intended to be exhaustive or to limit the invention to the precise forms disclosed, and it should be understood that many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. Many other variations are also to be considered within the scope of the present invention. For instance: the calculation of the present specification is applicable to circumstances involving conductive materials, or non-conductive materials, or both, and the application of the method of the present invention to periodic gratings which include conductive materials is considered to be within the scope of the present invention; once the eigenvectors and eigenvalues of a wave-vector matrix [A] are calculated and cached, intermediate results, such as the permittivity, inverse permittivity, permittivity harmonics, inverse-permittivity harmonics, permittivity harmonics matrix, the inverse-permittivity harmonics matrix, and/or the wave-vector matrix [A] need not be stored; the compound matrix [V], which is equal to the product of the eigenvector matrix and the root-eigenvalue matrix, may be calculated when it is needed, rather than cached; the eigenvectors and eigenvalues of the matrix [A] may be calculated using another technique; a range of an intra-layer parameter or an incident-radiation parameter may consist of only a single value; the grid of regularly-spaced layer-property values and/or incident-radiation values for which the matrices, eigenvalues and eigenvectors are cached may be replaced with a grid of irregularly-spaced layer-property values and/or incident-radiation values, or a random selection of layer-property values and/or incident-radiation values; the boundary-matched system equation may be solved for the diffracted reflectivity and/or the diffracted transmittance using any of a variety of matrix solution techniques; the “ridges” and “troughs” of the periodic grating may be ill-defined; a one-dimensionally periodic structure in a layer may include more than two materials; the method of the present invention may be applied to gratings having two-dimensional periodicity; a two-dimensionally periodic structure in a layer may include more than two materials; the method of the present invention may be applied to any polarization which is a superposition of TE and TM polarizations; the ridged structure of the periodic grating may be mounted on one or more layers of films deposited on the substrate; the method of the present invention may be used for diffractive analysis of lithographic masks or reticles; the method of the present invention may be applied to sound incident on a periodic grating; the method of the present invention may be applied to medical imaging techniques using incident sound or electromagnetic waves; the method of the present invention may be applied to assist in real-time tracking of fabrication processes; the gratings may be made by ruling, blazing or etching; the grating may be periodic on a curved surface, such as a spherical surface or a cylindrical surface, in which case expansions other than Fourier expansions would be used; the method of the present invention may be utilized in the field of optical analog computing, volume holographic gratings, holographic neural networks, holographic data storage, holographic lithography, Zemike's phase contrast method of observation of phase changes, the Schlieren method of observation of phase changes, the central dark-background method of observation, spatial light modulators, acousto-optic cells, etc. In summary, it is intended that the scope of the present invention be defined by the claims appended hereto and their equivalents.

What is claimed is:

1. A method for reducing computation time of an analysis of diffraction of incident electromagnetic radiation from a periodic grating having a direction of periodicity, said analysis involving a division of said periodic grating into layers, with an initial layer corresponding to a space above said periodic grating, a final layer corresponding to a substrate below said periodic grating, and said periodic features of said periodic grating lying in intermediate layers between said initial layer and said final layer, a cross-section of said periodic features being discretized into a plurality of stacked rectangular sections, within each of said layers a permittivity and electromagnetic fields being formulated as a sum of harmonic components along said direction of periodicity, application of Maxwell's equations providing an intra-layer matrix equation in each of said intermediate layers equating a product of a wave-vector matrix and first harmonic amplitudes of one of said electromagnetic fields to a second partial derivative of said first harmonic amplitudes of said one of said electromagnetic fields with respect to a direction perpendicular to a plane of said periodic grating, said wave-vector matrix being dependent on intra-layer parameters and incident-radiation parameters, a homogeneous solution of said intra-layer matrix equation being an expansion of said first harmonic amplitudes of said one of said electromagnetic fields into first exponential functions dependent on eigenvectors and eigenvalues of said wave-vector matrix, comprising the steps of:
determination of a layer-property parameter region and a layer-property parameter-region sampling;
determination of a maximum harmonic order for said harmonic components of said electromagnetic fields;
calculation of required permittivity harmonics for each layer-property value in said layer-property parameter region determined by said layer-property parameter-region sampling;
determination of an incident-radiation parameter region and an incident-radiation parameter-region sampling;
calculation of said wave-vector matrix based on said required permittivity harmonics for said each layer-property value in said layer-property parameter region determined by said layer-property parameter-region sampling and for each incident-radiation value in said incident-radiation parameter region determined by said incident-radiation parameter-region sampling;
calculation of eigenvectors and eigenvalues of each of said wave-vector matrices for said each layer-property value in said layer-property parameter region determined by said layer-property parameter-region sampling and for said each incident-radiation value in said incident-radiation parameter region determined by said incident-radiation parameter-region sampling;
caching of said eigenvectors and said eigenvalues of said each of said wave-vector matrices in a memory; and
use of said eigenvectors and said eigenvalues for said analysis of said diffraction of said incident electromagnetic radiation from said periodic grating.

2. The method of claim 1 further comprising the step of caching in, said memory, said wave-vector matrices for said each layer-property value in said layer-property parameter region determined by said layer-property parameter-region sampling and for said each incident-radiation value in said incident-radiation parameter region determined by said incident-radiation parameter-region sampling.

3. The method of claim 2 further comprising the step of caching in, said memory, said required permittivity harmonics for said each layer-property value in said layer-property parameter region determined by said layer-property parameter-region sampling.

4. The method of claim 1 further comprising the step of calculating a product of a square root of each of said eigenvalues and a corresponding one of said eigenvectors for said each layer-property value in said layer-property parameter region determined by said layer-property parameter-region sampling and for said each incident-radiation value in said incident-radiation parameter region determined by said incident-radiation parameter-region sampling.

5. The method of claim 4 further comprising the step of caching in said memory, said product of said square root of said each of said eigenvalues and said corresponding one of said eigenvectors for said each layer-property value in said layer-property parameter region determined by said layer-property parameter-region sampling and for said each incident-radiation value in said incident-radiation parameter region determined by said incident-radiation parameter-region sampling.

6. The method of claim 1 wherein another of said electromagnetic fields is expressible as an expansion of second harmonic amplitudes into second exponential functions dependent on said eigenvectors and said eigenvalues of said wave-vector matrix, application of boundary conditions of said electromagnetic fields at boundaries between said layers provides a boundary-matched system matrix equation, and solution of said boundary-matched system matrix equation provides said diffraction of said incident electromagnetic radiation from said periodic grating, and wherein said use of said eigenvectors and said eigenvalues for said analysis of said diffraction of said incident electromagnetic radiation from said periodic grating comprises the step of:
discretization of a cross-section of a ridge of said periodic grating into a stacked set of rectangles on said substrate;
retrieval, from said memory, for each of said rectangles, of said eigenvectors and said eigenvalues of said wave-vector matrix based on said intra-layer parameter values of said each of said rectangles, and based on said incident-radiation parameter values of said incident electromagnetic radiation;
construction of said boundary-matched system matrix equation using said eigenvectors and said eigenvalues of said wave-vector matrices retrieved from said memory for said each of said rectangles; and
solution of said boundary-matched system matrix equation to provide said diffraction of said incident electromagnetic radiation from said periodic grating.

7. The method of claim 1 wherein said intra-layer parameters for one of said layers include an index of refraction of a material of said periodic features in said one of said layers, an index of refraction of said initial layer, a length of periodicity of said periodic features, a width of said periodic features in said one of said layers, and an offset distance of said periodic features in said one of said layers, and said incident-radiation parameters include an angle of incidence of said electromagnetic radiation and a wavelength of said electromagnetic radiation.

8. The method of claim 1 wherein within said each of said layers, any line directed normal to said periodic grating passes through a single material.

9. The method of claim 1 wherein said initial layer and said final layer are mathematically approximated as semi-infinite.

10. The method of claim 1 wherein said layer-property parameter region and said incident-radiation parameter region describe a hyper-rectangle.

11. The method of claim 1 wherein coefficients of said expansion of said harmonic amplitudes of said electromagnetic field into said exponential functions include factors which are elements of an eigenvector matrix obtained from said wave-vector matrix, and exponents of said expansion of said harmonic amplitudes of said electromagnetic field include factors which are square roots of eigenvalues of said wave-vector matrix.

12. The method of claim 11 wherein said layer-property parameter-region sampling is at a uniform density.

13. The method of claim 11 wherein said layer-property parameter-region sampling is at a non-uniform density.

14. The method of claim 12 wherein said layer-property parameter-region sampling is done on a uniform grid.

15. The method of claim 12 wherein said layer-property parameter-region sampling is done on a non-uniform grid.

16. The method of claim 11 wherein at least one dimension of said incident-radiation parameter region has a range of a single value.

17. The method of claim 11 wherein at least one dimension of said layer-property parameter region has a range of a single value.
